(19) United States
(12) Patent Application Publication
(10) Pub. No.: US 2026/0096067 A1
(43) Pub. Date: Apr. 2, 2026

(54) THERMAL MANAGEMENT OF A DISTRIBUTED SYSTEM

(71) Applicant: Dell Products L.P., Round Rock, TX (US)

(72) Inventors: TIMOTHY ALLEN SHEDD, Lithia, FL (US); BHAVESH GOVINDBHAI PATEL, Austin, TX (US)

(21) Appl. No.: 18/899,117

(22) Filed: Sep. 27, 2024

(51) Int. Cl. H05K 7/20; G06F 1/20

(52) U.S. Cl. CPC H05K 7/20836; H05K 7/20209; H05K 7/20281; H05K 7/20736; H05K 7/20772; G06F 1/206

(57) ABSTRACT

Methods, systems, and devices are provided for managing operation of data processing systems positioned in a rack and that may provide computer implemented services. To do so, an occurrence of a thermal management event may be identified by a management controller of a data processing system of the data processing systems. Based on the occurrence, first operation data for the data processing system may be obtained. Based on the first operation data, operating points may be obtained for a cooling system of the rear door heat exchanger and a cooling system of the data processing system. Using the operating points, operation of the cooling system of the rear door heat exchanger and operation of the cooling system of the data processing system may be set to obtain an updated rack. Using the updated rack, the computer implemented services may be provided.

### FIELD

Embodiments disclosed herein relate generally to management of data processing systems. More particularly, embodiments disclosed herein relate to systems and methods for thermal management of data processing systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIG. 1A shows a block diagram illustrating data processing systems in accordance with an embodiment.

FIG. 1B shows a schematic diagram illustrating a rack system in accordance with an embodiment.

FIGS. 2A-2G show interaction diagrams and data flow diagrams illustrating processes and interactions for facilitating a thermal regulation framework in accordance with an embodiment.

FIGS. 3A-3C show flow diagrams illustrating methods for managing operation of data processing systems positioned in a rack in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing data processing systems that may provide, at least in part, computer implemented services. The computer implemented services may be provided to any type and/or number of other devices and/or users of the data processing systems. Furthermore, the provided computer implemented services may be of any quantity and/or type of such services.

To provide the computer implemented services, data processing systems may include hardware components. For example, operation of these hardware components may facilitate various functionalities of a data processing system, thereby causing the data processing system to provide the computer implemented services.

However, the operation of said hardware components may generate heat. To regulate this heat, for example, data processing systems may include thermal components such as cooling systems that cool components of the data processing systems, and racks on which the data processing systems may be mounted may include rear door heat exchangers (RDHx) that supplement cooling to the data processing systems.

However, operation of the data processing systems (and therefore, operation of the rack) may generate heat faster than performance of processes for facilitating such cooling of the components may be completed.

Furthermore, due to lack of specific optimizations, such processes may be performed while consuming inefficient quantities of available computing resources such as power available to data processing systems positioned with the rack.

Consequently, inefficient resource consumption, a rate of heat generation that is faster than a current rate of heat dissipation, and/or any other effects that may be enabled by a lack of specific optimization of the operations may negatively impact the computer implemented services. For example, such services may be delayed and/or otherwise prevented entirely should heat damage the components, thereby preventing necessary functionalities of said components. Additionally, for example, excessive power consumption may deplete the rack's available power, causing workloads being performed and/or scheduled for performance by the data processing systems in the rack to be lost.

To decrease a likelihood of these negative impacts, a thermal regulation framework may be leveraged. To do so, the thermal regulation framework may include various portions, each being primarily facilitated at distinct levels of system control over the rack to optimize operation of the rack.

In an embodiment, a method for managing operation of data processing systems positioned in a rack is provided.

The method may include identifying, by a management controller of a data processing system of the data processing systems, an occurrence of a thermal management event; based on the occurrence: obtaining, by the management controller, first operation data for the data processing system; obtaining, by the management controller, operating points for a cooling system of a rear door heat exchanger and a cooling system of the data processing system; setting, by the management controller and using the operating points, operation of the cooling system of the rear door heat exchanger and operation of the cooling system of the data processing system to obtain an updated rack; and providing computer implemented services using the updated rack.

Each of the cooling systems of the data processing systems may operate independently from the cooling system of the rear door heat exchanger.

Obtaining the operating points may include calculating the operating points using an optimization algorithm.

The optimization algorithm may be incentivized to globally minimize power consumption by the cooling system of the data processing system.

The optimization algorithm may be further incentivized to maintain temperatures of the data processing system within predefined temperature ranges.

The optimization algorithm may be further incentivized to ensure completion of workloads performed by the data processing system within predefined time ranges.

The optimization algorithm may utilize an objective function that quantifies potential operating points for the cooling system of the data processing systems based, at least, on power consumption, the temperatures of the data processing system, and the predefined time ranges to complete the workloads.

The first operation data may include power consumption demands placed on the data processing system for completion of at least a portion of the workloads; internal server chassis temperatures of the data processing system; ambient temperature data of the rack; individual component temperatures of hardware components of the data processing system; and fan rotation speeds of fans of the cooling system of the data processing system.

The operating points for the cooling system of the rear door heat exchanger may also be based on second operation data for the rear door heat exchanger, the second operation data may include power consumption demands placed on the rear door heat exchanger; inlet and outlet air temperatures of the rear door heat exchanger; position data specifying locations of fans and other cooling components of the rear door heat exchanger relative to positions of the data processing systems in the rack; fan rotation speeds of the fans of the rear door heat exchanger; liquid flow control data for a liquid cooling path within the rack; and inlet and outlet fluid temperatures for the liquid cooling path.

A management controller of the rear door heat exchanger may be an embedded controller that operates independently from the management controller of the data processing system, and an orchestrator tasked with managing operation of the data processing systems positioned in the rack.

The method may further include notifying, by the management controller of the data processing system, a management controller of the rear door heat exchanger of the operating points prior to updating operation of hardware components of the data processing system to enable the rear door heat exchanger to proactively modify cooling behavior to compensate for the updating of the operation of the hardware components, wherein the thermal management event may be an event that initiated updating of the operation of the hardware components.

The rear door heat exchanger may be adapted to cool multiple of the data processing systems at a same rate.

The rack may include the data processing systems; the management controller of the data processing system; the rear door heat exchanger; the management controller of the rear door heat exchanger; and the orchestrator.

In an embodiment, a non-transitory media is provided. The non-transitory media may include instructions that when executed by a processor cause, at least in part, the computer-implemented method to be performed.

In an embodiment, a management controller of the data processing system is provided. The management controller of the data processing system may include the non-transitory media and a processor and may, at least in part, perform the method when the computer instructions are executed by the processor.

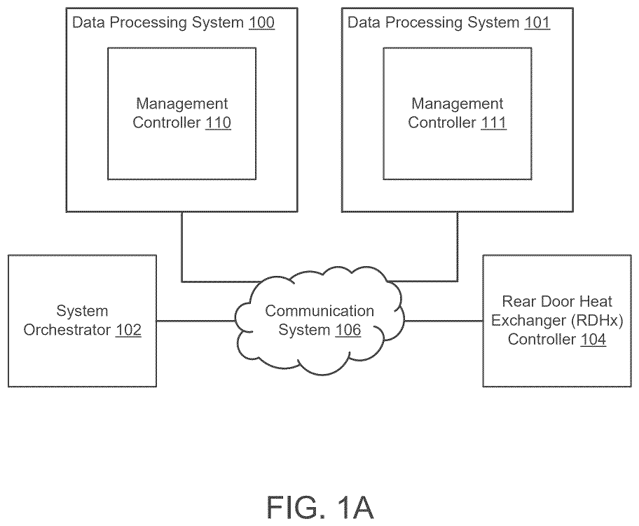

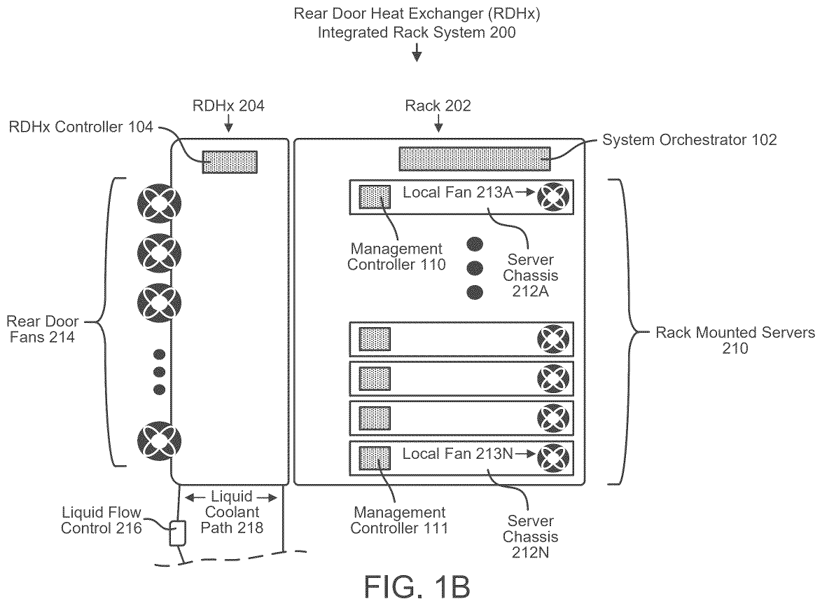

Turning to FIG. 1A, a block diagram illustrating a system in accordance with an embodiment is shown. The system shown in FIG. 1A may be a distributed system that provides computer implemented services.

The computer implemented services may include any type and quantity of computer implemented services. The computer implemented services may include, for example, database services, data processing services, electronic communication services, and/or any other services that may be provided using one or more computing devices.

Other types of computer implemented services may be provided by the system shown in FIG. 1A without departing from embodiments disclosed herein.

To provide the computer implemented services, the system may include any number of data processing systems (e.g., computing devices) such as data processing systems 100, and these data processing systems may each include any quantity of hardware components. These hardware components may include, for example, processors, memory modules, storage devices, communications devices, power components, and/or any other type of hardware component whose respective operations may facilitate various functionalities of the data processing systems. Facilitation of such functionalities of the data processing systems may thereby cause the computer implemented services to be provided.

However, operation of such hardware components may generate heat. This heat may cause damage to one or more components of the data processing systems if the heat is not dissipated. For example, prolonged exposure to heat and/or exposure to a temperature due to the heat that is not within a functional range (e.g., range of heat in which components operate optimally) may cause undesired effects on the data processing systems. These undesired effects may include physical damage, data corruption, high latency when executing operations, and/or other effects which may cause the computer implemented services to be delayed and/or prevented entirely.

To mitigate a likelihood of undesired effects caused by the heat, data processing systems may include thermal components such as cooling systems as illustrated and discussed with regard to FIGS. 1A-1B, below.

In general, embodiments disclosed herein relate to systems, devices, and methods for managing operation of data processing systems positioned in a rack. To do so, a thermal regulation framework may be leveraged.

The thermal regulation framework may include (i) obtaining data specifying conditions of devices positioned with the rack (e.g., server chassis humidity, processor temperatures, power consumption demands, cooling requirements, etc.), (ii) performing an optimization process using the obtained data to identify desirable operating points for various cooling systems for devices positioned with the rack, and (iii) setting the various cooling systems to the identified desirable operating points to obtain an updated rack. Using the updated rack, a likelihood of providing the services as desired may be increased due to the set operating points maintaining the range of heat in which the hardware components of the data processing systems operate optimally.

To provide the above noted functionality, the system of FIG. 1A may include data processing system 100, data processing system 101, system orchestrator 102, rear door heat exchanger (RDHx) controller 104, and communication system 106. Each of these components is discussed below.

Data processing system 100 and/or data processing system 101 may (i) provide computer implemented services, (ii) provide thermal management independently from one another for their respective components, (iii) request information from various devices (e.g., system orchestrator 102, RDHx controller 104, and/or other devices not explicitly shown in FIG. 1A) within the system, (iv) provide information (e.g., regarding changes to operations, current environment conditions, current operating conditions, etc.) to the various devices when prompted, and (v) cooperate with other computing devices in the system to facilitate the previously mentioned thermal regulation framework.

To provide their functionalities, data processing system 100 and data processing system 101 may include management controller 110 and management controller 111, respectively. These management controllers may facilitate operations of their respective data processing systems by utilizing internal networks of interconnections between components of the respective data processing systems. In doing so, the management controllers may direct operating conditions to change based on identified changes to, for example, workload demands, internal network traffic, and/or changes in the ambient environment. Additionally, these management controllers may be implemented as points of contact for the respective data processing systems. For example, should system orchestrator 102 attempt communication with data processing system 100, the communication may be intercepted by management controller 110, and thus obtained by data processing system 100. Such communication may also perform similarly in reverse. For example, should data processing system 100 attempt to initiate communication with system orchestrator 102, this communication may be provided via data transmitted by management controller 110 to system orchestrator 102.

System orchestrator 102 may operate as a senior-level management authority adapted to manage operation of computing devices positioned with the rack that have a limited scope of control over the devices within the rack. For example, such devices with limited scope of control may include the management controllers as discussed above, the management controllers capable of utilizing the internal networks of respective data processing systems, but unable to control operation of system orchestrator 102 and/or RDHx controller 104, discussed further below. Additionally, system orchestrator 102 may cooperate with other devices, like the management controllers, in the system to facilitate the previously mentioned thermal regulation framework.

To do so, system orchestrator 102 may (i) obtain first operation data for a rear door heat exchanger (RDHx) positioned with the rack, (ii) obtain second operation data for the data processing systems (e.g., 100-101), (iii) obtain first operating points for a cooling system of the rear door heat exchanger (RDHx) and second operating points for the cooling systems of the data processing systems using the first operation data and the second operation data, (iv) setting operation of the cooling system and the cooling systems using the first operating points and the second operating points to obtain an updated rack. Using the updated rack, the computer implemented services may be more likely provided as desired and/or requested.

Rear door heat exchanger (RDHx) controller 104 may (i) manage operation of components of the RDHx positioned with the rack, (ii) cause additional thermal management to be provided for the data processing systems, (iii) receive information from various devices (e.g., system orchestrator 102, management controllers 110-111, and/or other devices not explicitly shown in FIG. 1A) within the system, (iv) provide information (e.g., regarding changes to operation of the RDHx, current operating conditions of cooling components of the RDHx, etc.) to the various devices when prompted, and (v) cooperate with other computing devices in the system to facilitate the previously mentioned thermal regulation framework.

For additional information regarding components of devices positioned with the rack, refer to FIG. 1B, further below.

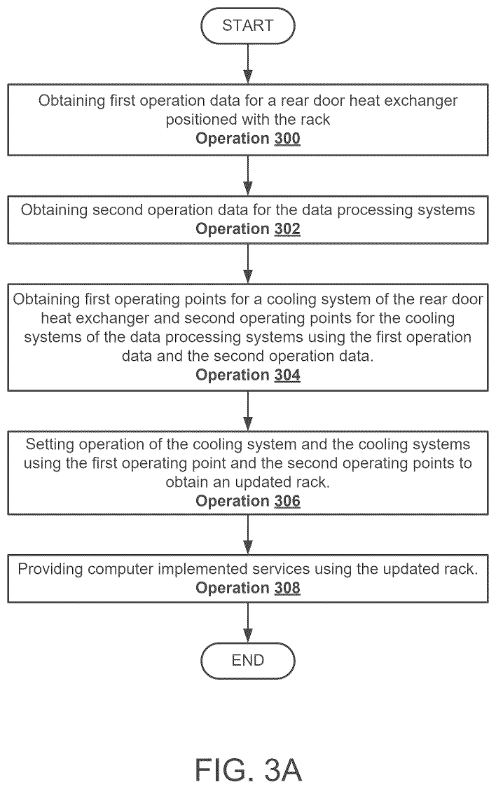

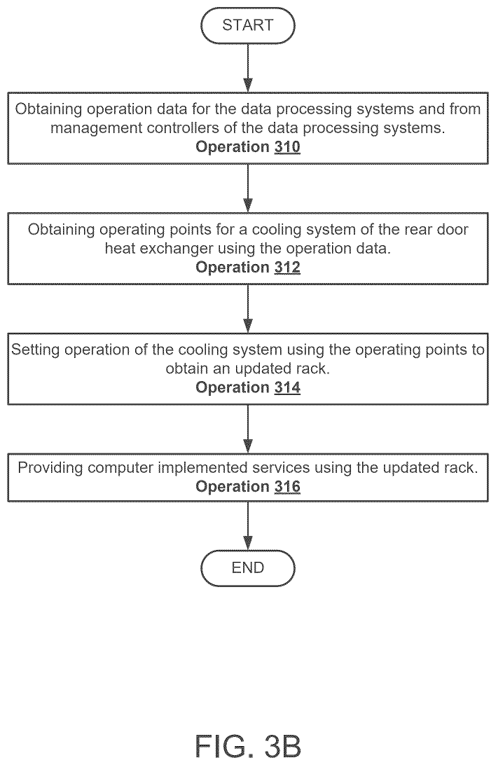

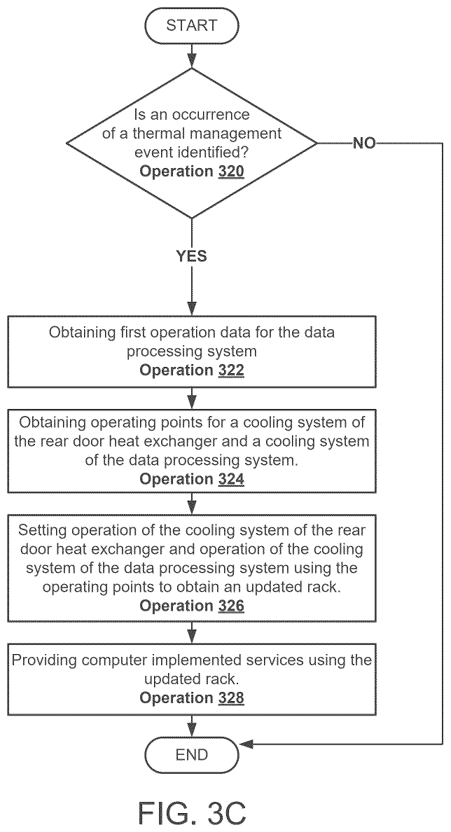

When providing their functionality, data processing systems 100-101, system orchestrator 102, and/or RDHx controller 104 may perform all, or a portion, of the methods shown in FIGS. 3A-3C. Any devices (and/or components thereof) positioned with the rack may be implemented using a computing device (also referred to as a data processing system) such as a host or a server, a personal computer (e.g., desktops, laptops, and tablets), a “thin” client, a personal digital assistant (PDA), a Web enabled appliance, a mobile phone (e.g., Smartphone), an embedded system, local controllers, an edge node, and/or any other type of data processing device or system.

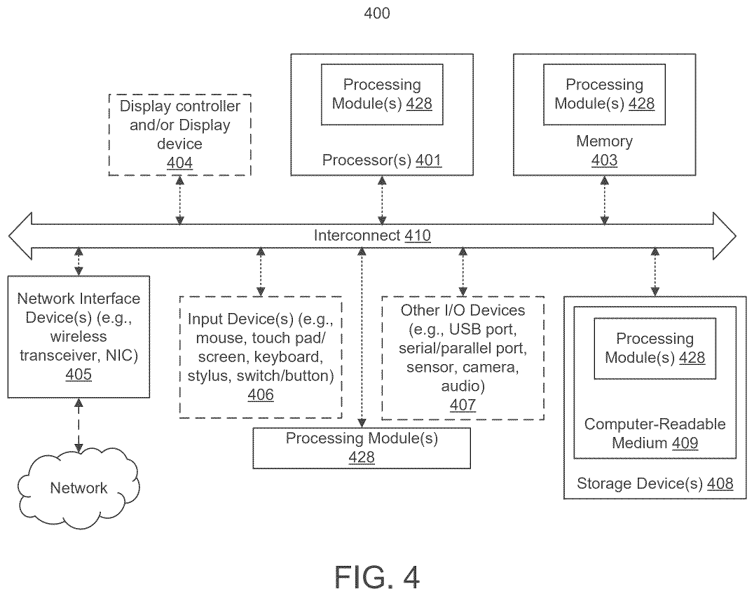

For additional details regarding computing devices, refer to FIG. 4.

Any of the components illustrated in FIG. 1A may be operably connected to each other (and/or components not illustrated) with a communication system of the rack (e.g., 106) utilized by data processing systems 100-101, system orchestrator 102, and RDHx controller 104 to, for example, cooperate with one another to facilitate the thermal regulation framework.

In an embodiment, this communication system may include one or more networks that facilitate communication between any number of components. The networks may include wired networks and/or wireless networks (e.g., and/or the Internet). The networks may operate in accordance with any number and types of communication protocols (e.g., such as the internet protocol).

While illustrated in FIG. 1A as including a limited number of specific components, a system in accordance with an embodiment may include fewer, additional, and/or different components than those illustrated therein.

Turning to FIG. 1B, a schematic diagram illustrating a rear door heat exchanger (RDHx) integrated rack system (e.g., 200) in accordance with an embodiment is shown. The system shown in FIG. 1B may include management controllers 110-111, system orchestrator 102, and RDHx controller 104, each of these components adapted to cooperate with one another (at least in part) to facilitate the thermal regulation framework, for example, within the system of FIG. 1B.

To provide the above noted functionality, RDHx integrated rack system 200 (e.g., and/or otherwise be regarded as “the rack system”) may include (i) rack 202 and (ii) RDHx 204. Each of these, and components thereof, are discussed below.

Rack 202 may be a rack mount chassis system adapted to house any number of data processing systems capable of providing computer implemented services in a complex multi-computing environment. For example, data processing systems 100 and 101 (discussed with regard to FIG. 1A) may be mounted with rack 202 and operably connected to other devices positioned with rack 202 (e.g., devices of RDHx integrated rack system 200). Rack 202 may include, for example, (i) rack mounted servers 210 and (ii) system orchestrator 102, each of which is discussed below.

Rack mounted servers 210 may include respective servers of the any number of data processing systems, vertically stacked relative to one another in rack 202. These respective servers may include, for example, servers 212A-212N.

Server chassis 212A-212N may be implemented with enclosures adapted to house hardware components of the data processing systems. For example, server chassis 212A may be a respective server chassis of data processing system 100, and thus, may house management controller 110 along with cooling components of data processing system 100 such as local fan 213A. Similarly, for example, server chassis 212N may be a respective server chassis of data processing system 101, and thus, may house management controller 111 along with cooling components of data processing system 101 such as local fan 213N.

As previously discussed, to provide the computer implemented services, the hardware components housed in each of rack mounted servers 210 may perform operations that facilitate functionalities of the data processing systems, thereby causing the computer implemented services to be provided. To perform these operations, the hardware components may consume power and generate heat.

To provide thermal management for the hardware components, the previously mentioned thermal regulation framework may be facilitated (at least in part) by cooling systems of the data processing systems (and/or a cooling system of the RDHx, discussed further below), thereby regulating the heat generated from performing the operations.

To provide the above noted functionality, the cooling systems may rely on functionality of, for example, (i) management controllers 110-111, respectively, and (ii) local fans 213A-213N positioned with respective server chassis. Each of these is discussed below.

Management controllers 110-111 may be implemented with computing devices (e.g., computer chips) that are operably connected to internal/local networks of respective data processing systems. These internal/local networks may be made up of, for example, interconnections between hardware components housed in the respective server chassis.

Based on the architecture of the internal/local networks within RDHX integrated rack system 200, the management controllers may have limited management authority over devices of RDHx integrated rack system 200. For example, management controller 110 may be limited to managing operation of hardware components of data processing system 100, and management controller 111 may be limited to managing operation of hardware components of data processing system 101. Hence, these management controllers may not have capability to manage one another's operation, nor may they have capability to manage operation of system orchestrator 102 and/or RDHx 204 (e.g., operation of RDHx controller 104). However, system orchestrator 102 may have such capability as to manage operation of any management controller (e.g., 110 and/or 111) of rack mounted servers 210.

As discussed with regard to FIG. 1A, system orchestrator 102 may operate as a senior-level management authority adapted to manage operation of computing devices positioned with the rack that have a limited scope of control over the devices within the rack. These computing devices may be, for example, management controllers 110-111.

To do so, system orchestrator 102 may be implemented with a computing device (e.g., a computer chip) that is operably connected to a local network of RDHx integrated rack system 200. This local network may be made up of, for example, interconnections between rack 202, the data processing systems of rack mounted servers 210, and RDHx 204. Thus, such interconnections may facilitate the senior-level of control within the system shown in FIG. 1B.

RDHx 204 may be adapted to supplement cooling for rack mounted servers 210. To provide this functionality, RDHx 204 be implemented with a back portion of the enclosure of rack 202 that allows a cooling system of RDHx 204 to, for example, cool the various data processing systems of rack mounted servers 210. For example, to cool the various data processing systems, RDHx 204 (e.g., the cooling system of RDHx 204) may include (i) RDHx controller 104, (ii) rear door fans 214, (iii) liquid flow control 216, and (iv) liquid coolant path 218. Each of these is discussed below.

RDHx Controller 104 may be implemented with a computing device (e.g., a computer chip) that is operably connected to components of the cooling system of RDHx 204. RDHx controller 104, as discussed with regard to FIG. 1A, may manage operation of components of the RDHx (204) that are positioned with the rack (202) to provide additional thermal management for the data processing systems (of rack mounted servers 210). In doing so, RDHx controller 104 may cooperate with other computing devices, such as system orchestrator 102 and management controllers 110-111, in the systems shown in FIGS. 1A-1B, to facilitate the previously mentioned thermal regulation framework.

Rear door fans 214 may be implemented with fans positioned with RDHx 204 (e.g., mounted on the back side of rack 202). This position of rear door fans 214 may facilitate an alignment between the fans and rack mounted servers 210 that allows for supplemental cooling to be provided, based on the thermal regulation framework, to the data processing systems.

Liquid flow control 216 and liquid coolant path 218 may be implemented with (at least a portion of) a liquid cooling portion of the cooling system of RDHx 204. For example, liquid flow control 216 may be a liquid cooling pump that may be used to control the rate of flow through a liquid cooling system, this rate of flow either increasing or decreasing depending on thermal requirements of the data processing systems, and ultimately, commands received from, for example, RDHx controller 104.

Liquid coolant path 218 may be implemented with tubes positioned throughout RDHx integrated rack system 200 such that a coolant whose rate of flow is controlled by liquid flow control 216 may flow through the tubes to dissipate at least a portion of the heat generated by the data processing systems.

Although not explicitly shown in FIG. 1B, these tubes may facilitate fluid communication between RDHx 204 and, for example, a liquid cooling block of data processing system 100. Therefore, for example, heated coolant may flow from data processing system 100 (e.g., the coolant being heated due to heat generated during operation of data processing system 100), to RDHx 204 where the heat from the heated coolant is dissipated by, for example, a heat exchanger of RDHx 204. The coolant may then flow away from RDHx 204 and back to data processing system 100 to repeat this dissipation of heat by the coolant.

Therefore, as discussed with regard to FIGS. 1A-1B, management controllers of data processing systems, a system orchestrator with senior-level management authority over a rack, and an RDHx controller of a RDHx (positioned with the rack) may each cooperate with one another to facilitate the previously mentioned thermal regulation framework.

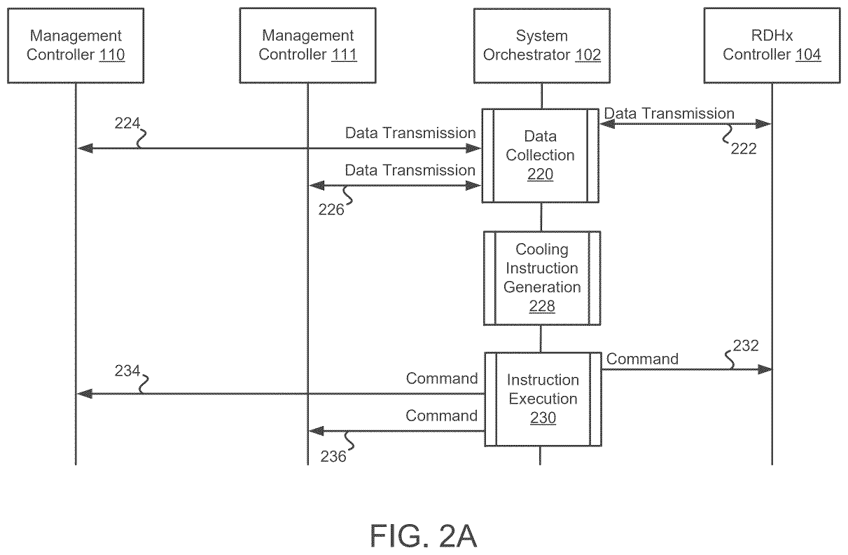

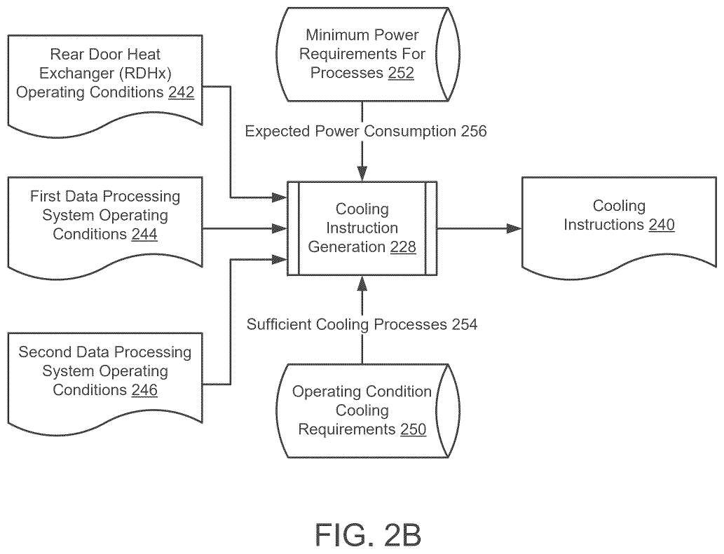

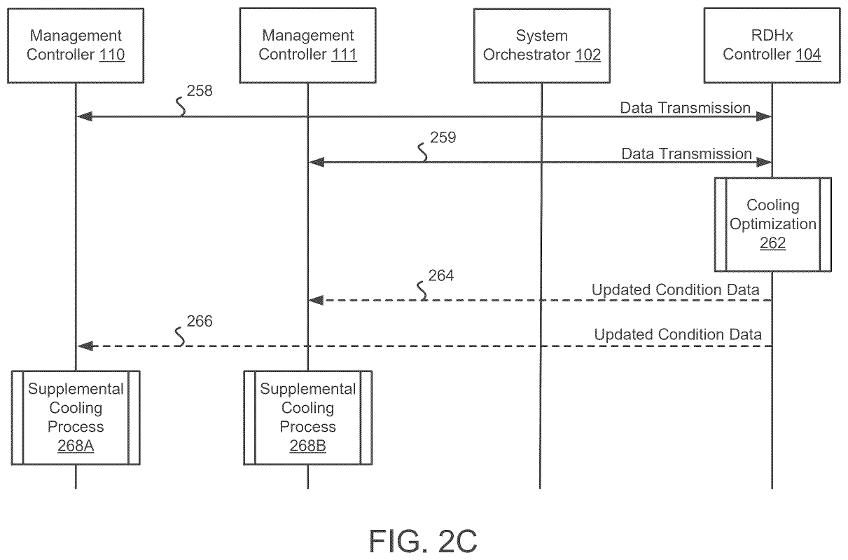

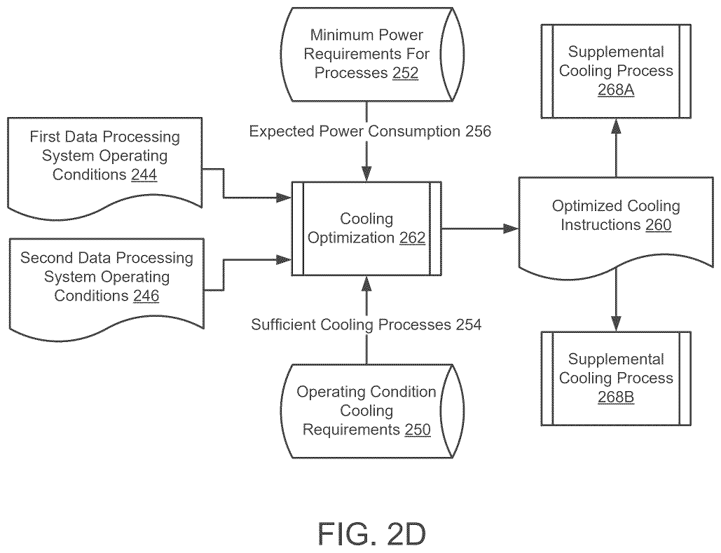

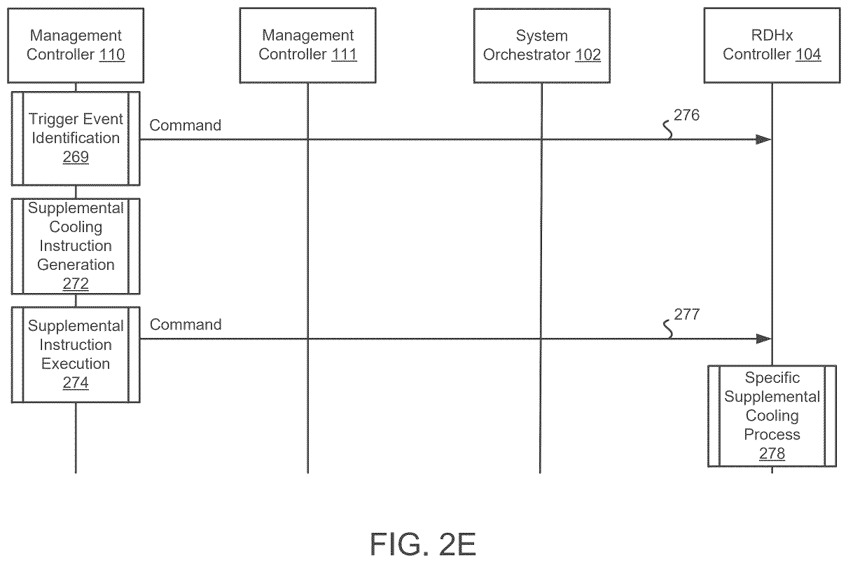

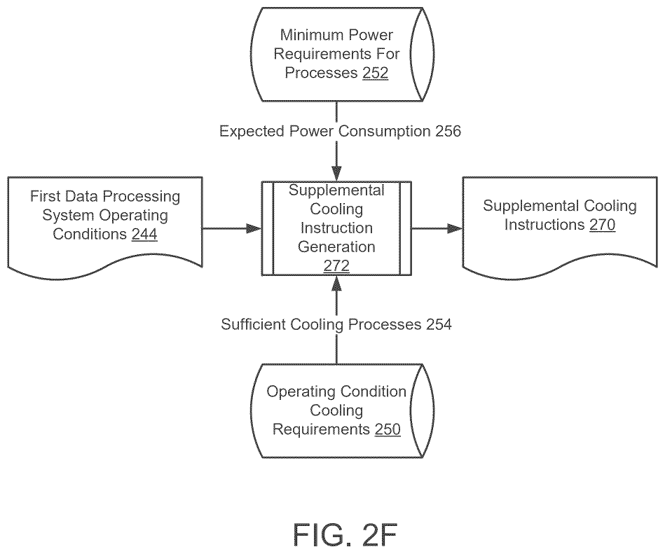

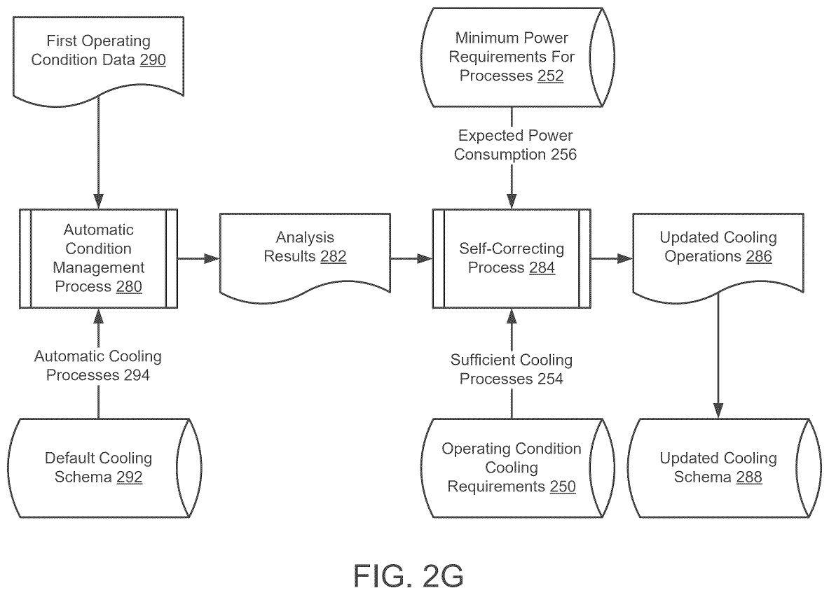

By facilitating such a framework, heat generated by hardware component operation within RDHx integrated rack system 200 may be sufficiently dissipated while mitigating power consumption of the rack, and therefore, mitigating power consumption of the hardware components therein. For example, such a framework may be facilitated as discussed with regard to FIGS. 2A-3C, discussed further below.

It will be appreciated that while discussed with regard to FIGS. 2A-3C, the thermal regulation framework may include various portions (e.g., a first, a second, and a third portion) that may each be primarily facilitated by specific entities of RDHx integrated rack system 200. For example, the first portion of the framework may be primarily facilitated by system orchestrator 102, the second portion of the framework may be primarily facilitated by RDHx controller 104, and the third portion of the framework may be primarily facilitated by either of management controllers 110 and/or 111 (and/or facilitated by any of the other data processing systems of rack mounted servers 210).

Thus, by facilitating such a framework as the thermal regulation framework (e.g., at least in part), there may be an increased likelihood of providing computer implemented services as expected/desired by a requestor of such services, the services being based on hardware component operation of at least one data processing system (e.g., workloads performed by the at least one data processing systems).

While illustrated in FIG. 1B with a limited number of specific components, a system may include additional, fewer, and/or different components without departing from embodiments disclosed herein.

To further clarify embodiments disclosed herein, interactions diagrams and data flow diagrams in accordance with an embodiment are shown in FIGS. 2A-2G. These interactions diagrams and data flow diagrams may illustrate how data may be obtained and used within the system of FIGS. 1A-1B.

In the interaction diagrams (e.g., in the context of these interaction diagrams rather than in the context of the data flow diagrams, discussed further below), such as in FIG. 2A, processes performed by and interactions between components of a system (e.g., the system of 1A and/or 1B) in accordance with an embodiment are shown. In these interaction diagrams, components of the system are illustrated using a first set of shapes (e.g., management controller 110, management controller 111, system orchestrator 102, RDHx controller 104, etc.), located towards the top of each figure. Lines descend from these shapes. Processes performed by the components of the system are illustrated using a second set of shapes (e.g., data collection 220, cooling instruction generation 228, instruction execution 230, etc.) superimposed over these lines. Interactions (e.g., communication, data transmissions, etc.) between the components of the system are illustrated using a third set of shapes (e.g., data transmission 222-226, command 232-236, etc.) that extend between the lines. The third set of shapes may include lines terminating in one or two arrows. Lines terminating in a single arrow may indicate that one-way interactions (e.g., data transmission from a first component to a second component) occur, while lines terminating in two arrows may indicate that multi-way interactions (e.g., data transmission between two components) occur.

Generally, the processes and interactions are temporally ordered in an example order, with time increasing from the top to the bottom of each page. For example, the interaction labeled as data transmission 226 may occur prior to the interaction labeled as command 236. However, it will be appreciated that the processes and interactions may be performed in different orders, any may be omitted, and other processes or interactions may be performed without departing from embodiments disclosed herein.

In the data flow diagrams, such as in FIG. 2B, flows of data and processing of data are illustrated using different sets of shapes also. In the context of these data flow diagrams (rather than in the context of the interaction diagrams, discussed above), a first set of shapes (e.g., 242, 244, etc.) is used to represent data structures, a second set of shapes (e.g., 228, etc.) is used to represent processes performed using and/or that generate data, and a third set of shapes (e.g., 250, 252, etc.) is used to represent large scale data structures such as databases (e.g., that include some type of schema).

Turning to FIG. 2A, a first interaction diagram in accordance with an embodiment is shown. The first interaction diagram may illustrate first processes and first interactions that may occur as at least part of a thermal regulation framework, previously discussed with regard to FIGS. 1A-1B. As shown in FIG. 2A, this thermal regulation framework may, at least in part (e.g., a first portion of this framework may), be primarily facilitated by system orchestrator 102.

It will be appreciated that while discussed with regard to system orchestrator 102 and the first portion of the framework in FIGS. 2A-2B, RDHx controller 104 and management controllers 110-111 may be discussed with regard to the second portion of the framework in FIGS. 2C-2D and/or a third portion of the framework in FIGS. 2E-2G, respectively, further below (refer to FIGS. 2C-2D and FIGS. 2E-2G, respectively, for additional information regarding the other portions of the framework).

To facilitate the first portion of this framework, system orchestrator 102 may initiate performance of data collection 220. This process of data collection may be based, for example, on identification of a trigger event. For example, a trigger event may include identification of additional workload requests being provided to any of the data processing systems mounted with the rack (e.g., a workload performance request obtained by data processing system 100). In this example, system orchestrator 102 may obtain communications indicative of this request thereby facilitating identification of the trigger event.

For example, such communications may include (i) receiving, from data processing system 100 (and therefore, management controller 110), a data transmission specifying occurrence of the request, (ii) obtaining the request directly (e.g., intercepting such a request before forwarding/providing it to management controller 110), (iii) data transmissions from components of the rack that identify condition changes associated with the first data processing system (e.g., immediate additional heat generation caused by an immediate attempt at performing, by the first data processing system, the requested workload), (iv) data transmissions from other components of the rack that specify identified changes in the ambient environment indicative of changes to operations being performed by the data processing systems (e.g., as discussed with regard to the immediate attempt at performing the workload), and/or (v) by some other means not to be limited by embodiments discussed herein.

During data collection 220, (i) requests may be provided to various devices in the rack via data transmissions (e.g., 222-226), (ii) based on the requests, respective operation data may be obtained for the various devices via similar data transmissions (e.g., 222-226), and (iii) the obtained operation data may be processed and/or otherwise parsed to identify correct associations between devices, several operating conditions and requirements, and respective data regarding such operating conditions and requirements of said devices (e.g., processes, such as cooling processes, to be performed in order to maintain operations within thresholds of the respective requirements).

For example, at interaction 222, the data transmission may include a first request and may be provided to RDHx controller 104 by system orchestrator 102. The first request may initiate commands from RDHx controller 104 to obtain data regarding operating states and conditions from components of the RDHx (e.g., components of RDHx 204 in FIG. 1B). Assuming that these components of the RDHx include (at least) those discussed with respect to FIG. 1B, the obtained data may include, (i) power consumption demands placed on the RDHx, (ii) temperatures of individual components of the RDHx, (iii) position data specifying locations of fans and other cooling components of the RDHx relative to positions of server chassis of data processing systems mounted in the rack, (iv) fan rotation speeds of the fans of the RDHx, (v) liquid flow control data for a liquid cooling path within the rack, and/or (vi) other data specifying ongoing operations of the RDHx components and conditions in which the such operations are ongoing.

Furthermore, as part of interaction 222, the data transmission may include this data, the data being provided to system orchestrator 102 by RDHX controller 104 based on the first request.

By providing this data based on the first request, system orchestrator 102 may process this data to obtain RDHx operating conditions (e.g., 242 discussed further below with respect to FIG. 2B).

At interaction 224, the data transmission may include a second request and may be provided to management controller 110 by system orchestrator 102. The second request may initiate commands from management controller 110 to obtain data regarding operating states and conditions from components of a first data processing system (e.g., 100 in FIG. 1A) in which management controller 110 is a part. Assuming that these components of the first data processing system include (at least) those discussed with respect to FIGS. 1A-1B, the obtained data may include first data processing system operating conditions 244, as discussed with regard to FIG. 2B, below.

As part of interaction 224, the data transmission may include this data (e.g., first data processing system operating conditions 244, as discussed with regard to FIG. 2B), the data being provided to system orchestrator 102 by management controller 110 based on the second request. By providing this data to be processed by system orchestrator 102 based on the second request, system orchestrator 102 may process this data during a cooling instruction generation as discussed further below, to obtain cooling instructions for the first data processing system (e.g., at least a portion of cooling instructions 240 discussed further below with respect to FIG. 2B).

Similar to interaction 224, at interaction 226, the data transmission may include a third request and may be provided to management controller 111 by system orchestrator 102. The third request may initiate commands from management controller 111 to obtain data regarding operating states and conditions from components of a second data processing system (e.g., 101 in FIG. 1A) in which management controller 111 is a part. Assuming that these components of the second data processing system include (at least) those discussed with respect to FIGS. 1A-1B, the obtained data may include second data processing system operating conditions 246, as discussed with regard to FIG. 2B, below.

As part of interaction 226, the data transmission may include this data (e.g., second data processing system operating conditions 246, as discussed with regard to FIG. 2B), the data being provided to system orchestrator 102 by management controller 111 based on the third request. By providing this data to be processed by system orchestrator 102 based on the third request, system orchestrator 102 may process this data during a cooling instruction generation, previously mentioned, and as discussed further below, to obtain cooling instructions for the second data processing system (e.g., at least a portion of cooling instructions 240 discussed further below with respect to FIG. 2B).

To further facilitate the first portion of the framework, cooling instruction generation 228 may be performed. During cooling instruction generation 228, the operating conditions for (i) the RDHx, (ii) the first data processing system, and (iii) the second data processing system may be used to obtain cooling instructions for devices (e.g., the RDHx, the first data processing system, and/or the second data processing system) positioned with the rack.

By performing cooling instruction generation 228, cooling instructions may be obtained that when performed (e.g., adhered to) (i) mitigate power consumption of the rack while (ii) preventing workloads performed by the data processing systems from being lost and (iii) maintaining sufficient cooling of the data processing systems mounted in the rack as the data processing systems perform the workloads.

Therefore, to implement the cooling instructions, instruction execution 230 may be performed. During instruction execution 230, interactions 232-236 may be initiated as discussed below.

For additional information regarding performance of cooling instruction generation 228, refer to FIG. 2B further below.

At interaction 232, a command may be provided to RDHx controller 104 by system orchestrator 102 that includes at least a first portion of the cooling instructions (e.g., the first portion of the cooling instruction including instructions pertaining to the RDHx and a cooling system thereof). For example, the first portion of the cooling instructions may be indicative of operations performable by components of the RDHx. Therefore, by providing at least the first portion of the cooling instructions to RDHx controller 104, RDHx controller 104 may cause the components of the RDHx (e.g., rear door fans 214 and/or liquid flow control 216 in FIG. 1B) to operate (e.g., perform operations) as specified by RDHx controller 104 based on the cooling instructions.

Similarly, at interactions 234 and 236, commands may be provided to management controllers 110-111 by system orchestrator 102 that respectively include at least a second portion of the cooling instructions and/or at least a third portion of the cooling instructions (e.g., the second portion of the cooling instruction including instructions pertaining to the first data processing system, and the third portion of the cooling instruction including instructions pertaining to the second data processing system).

For example, by providing management controller 110 commands specifying at least the second portion of the cooling instructions, management controller 110 may cause the components of the first data processing system to operate (e.g., perform operations) as specified by the commands to management controller 110. Similarly, for example, by providing management controller 111 commands specifying at least the third portion of the cooling instructions, management controller 111 may cause the components of the second data processing system to operate (e.g., perform operations) as specified by the commands to management controller 111.

Therefore, by providing at least the first portion of the cooling instructions to RDHx controller 104, at least the second portion of the cooling instructions to management controller 110, and at least the third portion of the cooling instructions to management controller 111, the first portion of the framework may be primarily facilitated by system orchestrator 102.

Thus, as shown in FIG. 2A, at least a first portion of the thermal regulation framework may allow for an optimized cooling instruction of the system shown in FIGS. 1A-1B that takes into consideration various demands placed on, for example, RDHx integrated rack system 200 from FIG. 1B (these various demands being placed, in part, on various devices positioned with the rack that are individually acknowledged and processed by system orchestrator 102). Therefore, as shown in FIG. 2A, the first portion of the framework may be primarily facilitated by system orchestrator 102.

Turning to FIG. 2B, a first data flow diagram in accordance with an embodiment is shown. The first data flow diagram may illustrate data used in and data processing performed in at least part of the thermal regulation framework, for example, discussed above with regard to the first portion of the framework in FIG. 2A (e.g., and thus, primarily facilitated by system orchestrator 102).

For example, to facilitate the first portion of the framework, cooling instruction generation 228 may be performed to obtain cooling instructions 240 (e.g., the cooling instructions discussed with regard to FIG. 2A). During cooling instruction generation 228, (i) RDHx operating conditions 242, (ii) first data processing system operating conditions 244, and (iii) second data processing system operating conditions 246 may be ingested.

RDHx operating conditions 242, as discussed with regard to FIG. 2A, may include, (i) power consumption demands placed on the RDHx, (ii) temperatures of individual components of the RDHx, (iii) position data specifying locations of fans and other cooling components of the RDHx relative to positions of server chassis of data processing systems mounted in the rack, (iv) fan rotation speeds of the fans of the RDHx, (v) liquid flow control data for a liquid cooling path within the rack, and/or (vi) other data specifying ongoing operations of the RDHx components and conditions in which the such operations are ongoing.

Similarly, first data processing system operating conditions 244 and second data processing system conditions 246 may each include data specifying ongoing operations of the first data processing system and the second data processing system components, respectively, and conditions in which such operations are ongoing.

For example, first data processing system operating conditions 244 may include (i) power consumption demands placed on the first data processing system, (ii) internal server chassis temperatures of the first data processing system, (iii) ambient temperature data of the rack, (iv) individual component temperatures of the first data processing system, (v) fan rotation speeds of fans of the first data processing system, and/or (vi) other data specifying ongoing operations of the first data processing system and conditions in which the such operations are ongoing.

Similarly, for example, second data processing system operating conditions 246 may include (i) power consumption demands placed on the second data processing system, (ii) internal server chassis temperatures of the second data processing system, (iii) ambient temperature data of the rack, (iv) individual component temperatures of the second data processing system, (v) fan rotation speeds of fans of the second data processing system, and/or (vi) other data specifying ongoing operations of the second data processing system and conditions in which the such operations are ongoing.

Once ingested, RDHx operating conditions 242, first data processing system operating conditions 244, and second data processing system operating conditions 246 may be subjected to any number of filtering and analysis processes. Some of the filtering and analysis processes may be defined by schema maintained by, for example, (i) operating condition cooling requirements 250 and (ii) minimum power requirements for process 252, discussed below.

To perform the any number of filtering and analysis processes defined by the schema, cooling instruction generation 228 may further ingest, for example, listed processes that may be known to require specific cooling, equating to specific combinations of cooling from facilitated airflow and/or liquid cooling throughout the rack. These listed processes may be relevant conditions/operations of the RDHx, the first data processing system, and/or the second data processing system, and therefore, may be filtered from RDHx operating conditions 242, first data processing system operating conditions 244, and/or second data processing system operating conditions 246.

Once the relevant conditions/operations are obtained, part of the schema may be used to obtain the specific combinations of cooling from facilitated airflow and/or liquid cooling throughout the rack (e.g., various cooling processes already being generally associated with providing sufficient cooling for respective specific conditions/operations). For example, the relevant conditions/operations may be matched with processes associated with cooling requirements from operating condition cooling requirements 250 to obtain any number of the specific combinations.

For example, assume that to dissipate heat generated from additional workload performances requested of the first data processing system (e.g., by a consumer of computer implemented services), the operation data from the above-mentioned devices specifies a specific combination of cooling be performed. This specific combination of cooling may therefore be obtained, this specific combination (and/or other/the any number of the specific combinations obtained by similar means to provide sufficient cooling) may be depicted in FIG. 2B with sufficient cooling processes 254.

Once sufficient cooling processes 254 is obtained (e.g., ingested), another part of the schema may be used to obtain minimum power requirements for each of the any number of specific combinations. For example, for a respective specific combination, each of the any number of specific combinations may be matched with minimum power requirements required to perform the respective specific combination from minimum power (e.g., that are known based on historical data associated with various device operations) requirements for processes 252. In doing so, an expected power consumption may be obtained for each of the any number of the specific combinations (e.g., expected power consumption 256 may be obtained).

Once expected power consumption 256 is obtained (e.g., ingested), an analysis may be performed to identify a most efficient minimum power consumption of the any number of the specific combinations. For example, the most efficient minimum power consumption may be a lowest value associated with power consumption obtained by comparing each expected power consumption of expected power consumption 256.

For example, the most efficient minimum power consumption may be power consumed by components of the RDHx, the first data processing system, and the second data processing system that (i) minimizes power consumed by the two data processing systems, that (ii) provides enough power for the respective specific combination from sufficient cooling processes 254 that is associated with the most efficient minimum power consumption, and all while (iii) maintaining operations being performed by the two data processing systems to perform workloads that cause computer implemented services to be provided as desired and/or expected by consumers of the services.

The respective specific combination from sufficient cooling processes 254 that is associated with the most efficient minimum power consumption may be identified, and thus, cooling instructions 240 may be obtained.

In doing so, cooling instructions 240 may include a first, second, and/or third portion of the cooling instructions as discussed with respect to FIG. 2A. This first, second, and/or third portion of the cooling instructions may include, for example, first operating points and/or second operating points as mentioned further below with respect to FIG. 3A, the operating points being new conditions for respective devices to reflect based on the aforementioned commands.

Thus, as shown in FIG. 2B, RDHx operating conditions 242, first data processing system operating conditions 244, and second data processing system operating conditions 246 may be ingested by cooling instruction generation 228 to output cooling instructions 240 (these cooling instructions including the first and the second operating points).

For additional information and/or examples regarding how cooling instructions 240 may influence operations performed by the RDHx, the first data processing system, and/or the second data processing system, respectively, refer to FIG. 3A further below.

Turning to FIG. 2C, a second interaction diagram in accordance with an embodiment is shown. The second interaction diagram may illustrate second processes and second interactions that may occur as at least part of a thermal regulation framework, previously discussed with regard to FIGS. 1A-1B. As shown in FIG. 2C, this thermal regulation framework may, at least in part (e.g., a second portion of this framework may), be primarily facilitated by RDHx controller 104.

It will be appreciated that while discussed with regard to RDHx controller 104 and the second portion of the framework in FIGS. 2C-2D, management controllers 110-111 may be discussed with regard to the third portion of the framework in FIGS. 2E-2G (further below) similar to system orchestrator 102 discussed previously with regard to the first portion of the framework in FIGS. 2A-2B.

For additional information regarding the first portion of the framework, refer back to FIGS. 2A-2B, discussed previously.

For additional information regarding the third portion of the framework, refer to FIGS. 2E-2G, discussed further below.

To facilitate the second portion of this framework, RDHx controller 104 may initiate data transmissions 258 and 259. These data transmissions may be initiated based on, for example, identification of a trigger event. Such a trigger event may include, for example, (i) identification of additional workload requests being provided to any of the data processing systems mounted with the rack (e.g., a workload performance request obtained by data processing system 100, similarly discussed in FIGS. 2A-2B), (ii) identification of condition changes within an ambient environment surrounding the rack, (iii) identification of condition changes within the rack, and/or (iv) occurrence of an automatic RDHx functionality to periodically initiate these data transmissions, for example, as scheduled by a technician that services the rack. Thus, RDHx controller 104 may initiate data transmissions 258-259.

These first two interactions (258-259) may include communications between RDHx controller 104 and management controllers 110-111, respectively, that establish future communication pathways via operable connections within, for example, RDHx integrated rack system 200 in FIG. 1B.

In some cases, these interactions 258-259 may be included in the identification of the trigger event. For example, these interactions may include signaling to RDHx controller 104 occurrence of a triggering event for change in processes that facilitate ongoing cooling for the data processing systems (e.g., during performance of workloads that may cause the computer implemented services to be provided).

For example, the first data processing system may receive commands to initiate performance of a new workload, and instructions to prioritize this new workload above other ongoing and/or scheduled workloads. The first data processing system, having information indicative of required changes to meet new cooling requirements that are based on the new workload, may provide a data transmission (e.g., 258) to RDHx controller 104 specifying the required changes, the new cooling requirements, and/or, simply, a notification indicating performance of the new workload on short notice.

At interaction 258, for example and based on the required changes, the new cooling requirements, and/or any notification as indicated by the above, the data transmission may include a first request that may be provided to management controller 110 by RDHx controller 104.

The first request may initiate commands for management controller 110 to obtain data regarding operating states and conditions from components of the first data processing system. Assuming that these components of the first data processing system include (at least) those discussed which respect to rack mounted servers 210 in FIG. 1B (e.g., also previously mentioned with regard to FIG. 2A), the data regarding operating states and conditions may include first data processing system operating conditions 244, as previously discussed with regard to FIG. 2B.

Similarly, at interaction 259, the data transmission may include a second request that may be provided to management controller 111 by RDHx controller 104. The second request may initiate commands for management controller 111 to obtain data regarding operating states and conditions from components of the second data processing system.

Assuming that these components of the second data processing system include (at least) those discussed which respect to rack mounted servers 210 in FIG. 1B (e.g., also previously mentioned with regard to FIG. 2A), the data regarding operating states and conditions may include second data processing system operating conditions 246, as previously discussed with regard to FIG. 2B.

Therefore, as part of interactions 258-259, the data transmissions may include first data processing system operating conditions 244 and second data processing system operating conditions 246, the data being provided to RDHx controller 104 by management controllers 110-111, respectively, based on the first and the second request.

By providing such data based on the first and the second request, RDHx controller 104 may process such data during cooling optimization 262, discussed below.

During cooling optimization 262, the operating conditions for (i) the first data processing system and (ii) the second data processing system may be used to obtain optimized cooling instructions for the RDHx positioned with the rack. These optimized cooling instructions may be instructions that RDHx controller 104 may implement with its own respective components of the RDHx to cool the data processing systems uniformly (and in some cases, individually) such that, for example, a data processing system with the highest degree of cooling requirements is cooled, thereby making sure all the data processing systems are cooled sufficiently (being as the one in the most need is covered by the uniform cooling). This execution of the optimized cooling instructions may also be performed during cooling optimization 262.

In some cases, however, the RDHx may only have capability to almost completely meet (e.g., meet a threshold that is just under what is specified by cooling requirements) the data processing system's highest degree of cooling requirements. In such cases, the data processing systems may not all be met with sufficient cooling solely facilitated by the RDHx. Such cases may require supplemental cooling for individual, respective, data processing systems that may be supplied by themselves and/or by other means.

For example, based on performance of cooling optimization 262 and assuming the latter uniform cooling scenario over the former uniform cooling by the RDHx, updated condition data 264 and/or 266 may be provided to management controller 110 and/or management controller 111, respectively, by RDHx controller 104.

It will be appreciated that the dotted lines at interactions 264 and 266 may, for example, (i) be literal transmissions from RDHx controller 104, (ii) be an acknowledgement by the management controllers regarding changes to the environment that may be directly due to RDHx controller 104 operation, and/or (iii) be that same acknowledgement but without knowing such changes are facilitate by the operation of RDHx controller 104.

Regardless of which type of occurrence such changes (e.g., updated condition data 264-266) are obtained by the respective management controllers, each management controller may perform a respective, supplemental cooling process (268A-268B) during which a data processing system may supplement the remainder of cooling needed to meet the new cooling requirements of said data processing system.

It will further be appreciated that in some cases, RDHx controller 104 may be capable of performing supplemental cooling process 268A and/or 268B for the data processing systems. For example, the RDHx may be operable connected to RDHx controller 104 in such a way as to facilitate independent component control of a number of rear door fans of the RDHx. Therefore, if the outcome of cooling optimization 262 is, for example, that two of the rear door fans (a first fan aligned with the first data processing system and a second fan aligned with the second data processing system) operate at 50% maximum power, that the second data processing system is sufficiently cooled, and that the first data processing system requires supplemental cooling to be sufficiently cooled, then the RDHx may provide that required supplemental cooling. To do so, RDHx controller 104 may instruct the first fan to increase its operation to 80% maximum power while the second fan (and/or any other of the rear door fans) remain operating at the 50% maximum power, leaving the first and the second data processing systems sufficiently cooled.

For additional information regarding performance of cooling optimization 262, refer to FIG. 2D further below.

Thus, as shown in FIG. 2C, at least a second portion of the thermal regulation framework may allow for an optimized cooling instruction of the system shown in FIGS. 1A-1B that takes into consideration various demands placed on, for example, RDHx integrated rack system 200 from FIG. 1B. These various demands being placed, in part, on various devices positioned with the rack that are individually acknowledged and processed by RDHx controller 104. Therefore, as shown in FIG. 2A, the second portion of the framework may be primarily facilitated by RDHx controller 104.

Turning to FIG. 2D, a second data flow diagram in accordance with an embodiment is shown. The second data flow diagram may illustrate data used in and data processing performed in at least part of the thermal regulation framework, for example, discussed above with regard to the second portion of the framework in FIG. 2C (e.g., and thus, primarily facilitated by RDHx controller 104).

For example, to facilitate the second portion of the framework, cooling optimization 262 may be performed to obtain optimized cooling instructions 260 (e.g., the optimized cooling instructions discussed with regard to FIG. 2C).

For example, during cooling optimization 262, (i) first data processing system operating conditions 244 and (ii) second data processing system operating conditions 246 may be ingested as discussed with regard to cooling instruction generation 228 in FIGS. 2A-2B.

Additionally, it will be appreciated that RDHx controller 104 may also be able to obtain RDHx operating conditions 242 as discussed with regard to FIGS. 2A-2B). However, such operating conditions may already be accessible to RDHx controller 104, and therefore, may not be explicitly shown in FIGS. 2C-2D as being ingested into cooling optimization 262 despite being used (at least in part) by RDHx controller 104 during performance of cooling optimization 262.

Therefore, first data processing system operating conditions 244 and second data processing system conditions 246 may each include data specifying ongoing operations of the first data processing system and the second data processing system components, respectively, and conditions in which such operations are ongoing.

For example, assume the scenario in which the first data processing system receives a request to perform the new workload as well as the request for the prioritization of the new workload. First data processing system operating conditions 244 may therefore include power consumption demands placed on the first data processing system, internal server chassis temperatures of the first data processing system, (etc., etc.) as well as the required changes to meet new cooling requirements that are based on the new workload.

Similarly, second data processing system operating conditions 246 include similar data, but rather than be associated with the first data processing system, second data processing system operating conditions 246 may be associated with the second data processing system, as previously discussed.

Once ingested, first data processing system operating conditions 244 and second data processing system operating conditions 246 may be subjected to any number of filtering and analysis processes. Some of the filtering and analysis processes may be defined by schema maintained by (i) operating condition cooling requirements 250 and (ii) minimum power requirements for process 252, previously discussed with regard to FIG. 2B as well as discussed further below.

To perform the any number of filtering and analysis processes defined by the schema, cooling optimization 262 may include obtaining, for example, listed processes (and/or any number of combinations of the listed processes) that may be performable by the RDHx that are known to provide required specific cooling for the data processing systems. It will be appreciated, that in this context, for example, this required specific cooling is what is needed by RDHx integrated rack system 200 for the data processing systems to meet the new cooling requirements.

Such listed processes (and/or the any number of combinations of the listed processes) may be obtained using a first part of the schema that includes utilization of, for example, operating condition cooling requirements 250, as discussed with regard to FIG. 2B, to obtain sufficient cooling processes 254.

Once sufficient cooling processes 254 is obtained, another part of the schema may be used, for example, to obtain minimum power requirements for each of the any number of specific combinations. For a respective specific combination, each of the any number of specific combinations may be matched with minimum power requirements required to perform the respective specific combination from minimum power requirements for processes 252. In doing so, an expected power consumption may be obtained for each of the any number of the specific combinations (e.g., expected power consumption 256 may be obtained).

In contrast to the discussion of FIG. 2B, for example, expected power consumption 256 may only include power consumption values of operation performable by only the RDHx, and components thereof, rather than power consumption values of performable operations of the first data processing system and/or the second data processing system.

Once expected power consumption 256 is obtained, an analysis may be performed to identify a most efficient minimum power consumption of the any number of the specific combinations. For example, the most efficient minimum power consumption may be a lowest value associated with power consumption obtained by comparing each expected power consumption of expected power consumption 256.

For example, the most efficient minimum power consumption may be power consumed by components of the RDHx during whose cooling operations (i) minimize power consumed by the two data processing systems, (ii) provide enough power for the respective specific combination from sufficient cooling processes 254 that is associated with the most efficient minimum power consumption, and (iii) maintain operations being performed by the two data processing systems to perform workloads (e.g., the new workload) that cause computer implemented services to be provided as desired and/or expected by consumers of the services.

The respective specific combination from sufficient cooling processes 254 that is associated with the most efficient minimum power consumption may be identified, and thus, optimized cooling instructions 260 may be obtained.

In doing so, optimized cooling instructions 260 may include a first, second, and/or third portion of the cooling instructions as discussed with respect to cooling instructions 240 in FIG. 2A. This first, second, and/or third portion of the cooling instructions may include, for example, operating points as mentioned further below with respect to FIG. 3B, the operating points being new conditions for respective devices to reflect based on the aforementioned commands.

Thus, as shown in FIG. 2D, first data processing system operating conditions 244, and second data processing system operating conditions 246 may be ingested by cooling optimization 262 to output optimized cooling instructions 260.

As discussed with regard to FIG. 2C, these optimized cooling instructions (e.g., 260) may be facilitated by RDHx controller 104 to, for example, uniformly cool the data processing systems via operation of the RDHx (and components thereof) such that the data processing systems may only need very little supplemented cooling facilitated by their own means (and/or facilitated by the RDHx) and/or may not need any supplemental cooling at all due to already having the new cooling requirements met.

As shown in FIG. 2D, such required supplemental cooling processes (and/or a lack of supplemental cooling required) may be based on optimized cooling instructions 260 and depicted using optimized cooling instructions 260 being ingested into supplemental cooling processes 268A and 268B, individually. It will be appreciated that the way in which optimized cooling instructions 260 may be ingested is as discussed in FIG. 2C with regard to the dotted lines at interaction 264 and/or interaction 266.

For additional information and/or examples regarding how optimized cooling instructions 260 may influence operations performed by the RDHx, the first data processing system, and/or the second data processing system, respectively, refer to FIG. 3B further below.

Turning to FIG. 2E, a third interaction diagram in accordance with an embodiment is shown. The third interaction diagram may illustrate third processes and third interactions that may occur as at least part of a thermal regulation framework, previously discussed with regard to FIGS. 1A-1B. As shown in FIG. 2E, this thermal regulation framework may, at least in part (e.g., a third portion of this framework may), be primarily facilitated by management controller 110.

It will be appreciated that while system orchestrator 102 is discussed previously with regard to the first portion of the framework in FIGS. 2A-2B and RDHx controller 104 is discussed previously with regard to the second portion of the framework in FIGS. 2C-2D, similarly, management controller 110 may be discussed with regard to the third portion of the framework in FIGS. 2E-2G.

For additional information regarding the first portion and/or the second portion of the framework, refer back to FIGS. 2A-2B and/or FIGS. 2C-2D, respectively.

To facilitate the third portion of this framework, management controller 110 may (i) identify a trigger, (ii) perform a supplemental cooling instruction generation to obtain supplemental cooling instructions for the first data processing system, (iii) perform supplemental instruction execution to implement the obtained supplemental cooling instructions, and/or (iv) other processes and/or interactions may be facilitated.

To identify the trigger, for example, trigger event identification 269 may be performed. During trigger event identification 269, a likelihood of there being new cooling requirements that have not yet been met may be determined/obtained. To do so, immediate processes that are ongoing and/or of which performance is imminent, may be analyzed (e.g., compared) to determine whether known cooling requirements of said processes vary, and if they vary, to what degree of variance.

For example, assume that the first data processing system obtains a request to perform a new workload in addition to obtaining a request to prioritize said workload (e.g., as mentioned with regard to FIGS. 2C-2D). Further assume that there is a substantial variation between cooling requirements of the new workload and the cooling requirements of scheduled workloads to be performed by the first data processing system. For example, to accommodate performance of the new workload, operating conditions of the first data processing system may require updating. Therefore, management controller 110 may identify an occurrence of a trigger event.

Based on identification of the trigger event, (i) data regarding operating states and conditions from components of the first data processing system (e.g., first data processing system operating conditions 244 as discussed in FIGS. 2C-2D) may be obtained, and/or (ii) at interaction 276, for example, an automatic command may be provided to RDHx controller 104 for increasing cooling processes automatically. By increasing the cooling processes, RDHx controller 104 may cause the RDHx to increase a uniform cooling across all the data processing systems (and/or individually for the first data processing system) in anticipation of the new workload (possibly) having different cooling requirements than that which are currently being met.

It will be appreciated, however, that although described with regard to an automatic command to RDHx controller 104, in some cases, management controller 110 may not be capable of communication with the RDHx (e.g., at least be unable to receive data transmissions from the RDHx). For example, an inability to obtain data transmissions from RDHx controller 104 may prevent management controller 110 from acknowledging the RDHx and/or leave the first data processing system unaware of the RDHx altogether.

Thus, management controller 110 may facilitate an automatic condition management process during which the first data processing system may be self-correcting with regard to, for example, its own default cooling processes even while the RDHx provides supplemental cooling that management controller 110 is unaware of.

For additional information regarding the automatic condition management process, refer to FIG. 2G further below.

For example, identifying the new cooling requirements may take 11 seconds, and performing processes that are to make the first data processing system meet the new cooling requirements may take a full minute. However, the new workload may only take a second to begin its performance, and by being performed, may cause additional heat generation after 2 more seconds. Consequently, heat may generate too quickly before sufficient cooling is able to be applied by the first data processing system. Therefore, the automatic command may prevent overheating as the first data processing system is sufficiently cooled by, at least in part, supplemented cooling provided by the RDHx. While the supplemented cooling is provided, the first data processing system may be enabled to optimize its own operation (e.g., its self-performed cooling processes), thereby decreasing a likelihood of delaying and/or preventing performance of scheduled workloads (e.g., the new workload and previously scheduled workloads).

Once obtained (e.g., from components of the first data processing system), first data processing system operating conditions 244 may undergo any number of filtering and/or analysis processes similar to those previously discussed.

For example, to filter and/or analyze first data processing system operating conditions 244, supplemental cooling instruction generation 272 may be performed. During supplemental cooling instruction generation 272 supplemental cooling instructions (e.g., 270, discussed further below with regard to FIG. 2F) may be obtained.

These supplemental cooling instructions may be instructions that management controller 110 may implement with respective components of the first data processing system to cool itself such that, for example, the first data processing system is sufficiently cooled during performance of the new workload and any other workloads scheduled for performance. To do so, supplemental instruction execution 274 may be performed using the supplemental cooling instructions. For example, during supplemental instruction execution 274, performance of the supplemental cooling instructions may be executed.

Additionally, at interaction 277, for example, another command may be provided to RDHx controller 104 to either change or maintain the cooling initiated by the command at interaction 276 by the RDHx. This change or maintenance would be facilitated during specific supplemental cooling process 278 in which cooling provided by the RDHx may supplement cooling provided by a cooling system of the first data processing system. Such supplementation may be based on, for example, overall cooling operations (i) minimizing power consumed by the first data processing system, (ii) providing enough power for the overall cooling operations, and while (iii) maintaining operations being performed by the first data processing system to perform workloads (e.g., the new workload) that cause computer implemented services to be provided as desired and/or expected by consumers of the services.

For additional information regarding performance of supplemental cooling instruction generation 272, refer to FIG. 2F further below.

Thus, as shown in FIG. 2E, at least a third portion of the thermal regulation framework may allow for supplemental cooling instructions to be provided for data processing systems in the system shown in FIGS. 1A-1B. Also shown in FIG. 2F, the third portion of the framework may, for example, be primarily facilitated by management controller 110.

Turning to FIG. 2F, a third data flow diagram in accordance with an embodiment is shown. The third data flow diagram may illustrate data used in and data processing performed in at least part of the thermal regulation framework, for example, discussed above with regard to the third portion of the framework in FIG. 2E (e.g., and thus, primarily facilitated by management controller 110).

To facilitate the third portion of the framework, supplemental cooling instruction generation 272 may be performed to obtain supplemental cooling instructions 270 (e.g., the supplemental cooling instructions discussed with regard to FIG. 2E).

For example, during supplemental cooling instruction generation 272 first data processing system operating conditions 244 may be ingested as discussed with regard to cooling instruction generation 228 in FIGS. 2A-2B.

Therefore, first data processing system operating conditions 244 may include data specifying ongoing operations of the first data processing system's components and conditions in which such operations are ongoing.

For example, assume the scenario (mentioned previously with regard to FIG. 2E) in which the first data processing system receives the request to perform the new workload as well as the request for the prioritization of the new workload. First data processing system operating conditions 244 may therefore include power consumption demands placed on the first data processing system, internal server chassis temperatures of the first data processing system, (etc., etc.) as well as the required changes to meet new cooling requirements that are based on the new workload.

Once ingested, first data processing system operating conditions 244 may be subjected to any number of filtering and analysis processes. Some of the filtering and analysis processes may be defined by schema maintained by (i) operating condition cooling requirements 250 and (ii) minimum power requirements for process 252, previously discussed with regard to FIGS. 2B and 2D, as well as discussed further below.

To perform the any number of filtering and analysis processes defined by the schema, supplemental cooling instruction generation 272 may include obtaining, for example, listed processes (and/or any number of combinations of the listed processes) that may be performable by the first data processing system that are known to provide required specific cooling for the first data processing system. It will be appreciated that, with regard to the system of FIGS. 1A-1B for example, this required specific cooling is what is needed by RDHx integrated rack system 200 for the first data processing system to meet the new cooling requirements.

Such listed processes (and/or the any number of combinations of the listed processes) may be obtained using a first part of the schema that includes utilization of, for example, operating condition cooling requirements 250, as discussed with regard to FIGS. 2B and 2D, to obtain sufficient cooling processes 254.

Once sufficient cooling processes 254 is obtained, another part of the schema may be used, for example, to obtain minimum power requirements for each of the any number of specific combinations. For a respective specific combination, each of the any number of specific combinations may be matched with minimum power requirements required to perform the respective specific combination from minimum power requirements for processes 252. In doing so, an expected power consumption may be obtained for each of the any number of the specific combinations (e.g., expected power consumption 256 may be obtained).

In contrast to the discussion of FIGS. 2B and 2D, however, expected power consumption 256 may in some cases only include power consumption values of operations performable by only the first data processing system, and components thereof. This in contrast to, rather than power consumption values of performable operations of the RDHx and/or the second data processing system, cooling processes being primarily facilitated by the first data processing system (e.g., management controller 110).

Once expected power consumption 256 is obtained, an analysis may be performed to identify a most efficient minimum power consumption of the any number of the specific combinations. For example, the most efficient minimum power consumption may be a lowest value associated with power consumption obtained by comparing each expected power consumption of expected power consumption 256.

For example, the most efficient minimum power consumption may be power consumed by components of the first data processing system during whose cooling operations (i) minimize power consumed by the two data processing systems, (ii) provide enough power for the respective specific combination from sufficient cooling processes 254 that is associated with the most efficient minimum power consumption, and (iii) maintain operations being performed by the first data processing system to perform workloads (e.g., the new workload) that cause computer implemented services to be provided as desired and/or expected by consumers of the services.

The respective specific combination from sufficient cooling processes 254 that is associated with the most efficient minimum power consumption may be identified, and thus, supplemental cooling instructions 270 may be obtained.

Thus, as shown in FIG. 2F, first data processing system operating conditions 244 may be ingested by supplemental cooling instruction generation 272 to output supplemental cooling instructions 270.

As discussed with regard to FIG. 2E, these supplemental cooling instructions (e.g., 270) may be implemented by management controller 110 to, for example, cool the first data processing system via operation of the first data processing system (and components thereof). Additionally, in some cases, these supplemental cooling instructions may, at least in part, be implemented by the RDHx, such that the first data processing system may only need very little supplemented cooling facilitated by their own means and/or may not need any supplemental cooling at all due to already having the new cooling requirements automatically met by the RDHx (e.g., due to an automatic reaction of the RDHx based on the trigger identification discussed in FIG. 2E.

As shown in FIG. 2F, such required supplemental cooling processes may be automatic and/or based on supplemental cooling instructions 270, supplemental cooling instructions 270 being used in, for example, specific supplemental cooling process 278 (shown in FIG. 2E). It will be appreciated that some of the automatic and/or some of the process based supplemental cooling may be facilitated as described with respect to interactions 276 and/or 277 in FIG. 2E as well as with regard to the processes discussed in FIG. 2E.

For additional information and/or examples regarding how supplemental cooling instructions 270 may influence operations performed by the first data processing system and/or the RDHx, respectively, refer to FIG. 3C further below.

Turning to FIG. 2G, a fourth data flow diagram in accordance with an embodiment is shown. The fourth data flow diagram may illustrate data used in and data processing performed in at least part of the thermal regulation framework, for example, discussed above with regard to the third portion of the framework in FIG. 2E (e.g., and thus, primarily facilitated by management controller 110).

As shown in FIG. 2G, management controller 110 may, for example, facilitate an automatic condition management process (e.g., 280) for the first data processing system to maintain an operating efficiency while positioned in the rack.

For example, in some cases as discussed previously, the first data processing system may be incapable of obtaining communications such as data transmissions from other devices positioned with the rack such as the RDHx (and therefore, RDHx controller 104). Thus, management controller 110 may lack information regarding what other devices in the rack are doing and/or processes the other devices are scheduled to perform (e.g., unknown processes such as an automatic supplementation of cooling processes by the RDHx based on a trigger identification, discussed previously with regard to FIGS. 2E-2F).

Due to performance of supplementation processes being unknown to management controller 110, conditions in the rack may have a greater variance than expected by default cooling procedures of the first data processing system. Not only may there be greater variance than expected, but consequently, cooling processes performed by the first data processing system may contribute to (e.g., at least temporarily) unpredictable changes of operating conditions within the rack.

Therefore, to maintain the operating efficiency despite great variance in the outcome of processes, automatic condition management process 280 may be performed.

During automatic condition management process 280 (i) first operating condition data 290 may be ingested, and (ii) automatic cooling processes 294, obtained from default cooling schema 292, may be ingested.

First operating condition data 290 may be similar to the data discussed with regard to first data processing system operating conditions 244 in FIGS. 2A-2F. Therefore, first operating condition data 290 may include data specifying scheduled processes to be performed by the first data processing system as well as, for example, data specifying occurrence of a trigger event such as the new workload request that was previously discussed.

Automatic cooling processes 294 may include a combination of cooling processes that may be historically known to provide optimal cooling for the first data processing system. For example, such optimal cooling may provide sufficient cooling while minimizing power consumption while also mitigating workload loss and/or delays associated with performance of the workloads. This combination of cooling processes may be obtained from default cooling schema 292, a repository of operation data associated with various processes, various combinations of such processes, known resource consumption of such processes, outcomes historically associated with such processes, and/or other data regarding historical operation of the first data processing system.

Based on the ingestion of first operating condition data 290 and (ii) automatic cooling processes 294, automatic condition management process 280 may output analysis results 282.

Analysis results 282 may be new data regarding the outcome of operating conditions of the first data processing system after performance of, for example, automatic cooling processes 294. In some cases, this new data may align with the historical data from default cooling schema 292, thereby indicating that the performance of automatic cooling processes 294 has contributed to condition changes within the rack as expected. However, in other cases, this new data may not align with the historical data from default cooling schema 292, thereby indicating that the performance of automatic cooling processes 294 has contributed to unexpected condition changes within the rack.

Between the former and the latter of these cases, the latter cases may result in analysis results 282 being ingested into self-correcting process 284.

During self-correcting process 284, management controller 110 may perform adjustments to associations between processes and outcomes from performing such processes (e.g., and/or other data associated with the processes) to obtain updated cooling operation 286.

Along with ingestion of analysis results 282, to obtain updated cooling operation 286 as an output from self-correcting process 284, sufficient cooling process 254 from operating condition cooling requirements 250 and expected power consumption 256 from minimum power requirements for processes 252 may be ingested into self-correcting process 284. This ingestion may be performed as discussed in FIGS. 2B, 2D, and 2F.

Thus, the output of updated cooling operations 286 may be performable processes that when performed contribute to changes in the rack as expected. Additionally, it will be appreciated that updated cooling operations 286 may be ingested into automatic condition management process 280 to verify such expected contribution to the changes in the rack.

Once verified to contribute as expected, updated cooling operations 286 may be stored in updated cooling schema 288, updated cooling schema 288 being an updated version of default cooling schema 292, to be used in a similar manner as automatic cooling processes 294 during future occurrences of automatic condition management process 280.

For additional information and/or examples regarding how updated cooling operations 286 may influence operations performed by the first data processing system, refer to FIG. 3C further below.

Thus, as discussed with regard to FIGS. 2A-2G, a thermal regulation framework may be facilitated by any number of devices such as management controllers 110-111, system orchestrator 102, and/or RDHx controller 104 cooperating with one another as part of, for example, a RDHx integrated rack system (e.g., 200 in FIG. 1B). By cooperating with one another as defined by the thermal regulation framework, heat generated by hardware component operation within the rack may be sufficiently dissipated while mitigating power consumption of the rack. In doing so, power consumption of the hardware components therein may be mitigated also without worry or risk of workload loss.

Thus, by facilitating such a framework, there may be an increased likelihood of providing computer implemented services as expected/desired by a requestor of such services, the services being based on the hardware component operation (e.g., performance of the workloads).

While illustrated in FIGS. 2A-2G with a limited number of specific components, a system may include additional, fewer, and/or different components without departing from embodiments disclosed herein.

As discussed above, the components of FIGS. 2A-2G may facilitate and/or perform various functionalities to facilitate the thermal regulation framework for managing cooling of data processing systems. FIGS. 3A-3C illustrate methods that may be facilitated and/or performed by the components of FIGS. 2A-2G.

In the diagrams discussed below and shown in FIGS. 3A-3C, any of the operations may be repeated, performed in different orders, and/or performed in parallel with or in a partially overlapping in time manner with other operations.

Turning to FIG. 3A, a first flow diagram illustrating a method (e.g., a first method) for managing operation of data processing systems positioned in a rack in accordance with an embodiment is shown. The method may be performed, for example, by a system orchestrator, and/or any other entity.

For example, the first method may be that which is discussed with respect to a first portion of a thermal regulation framework as discussed with respect to FIGS. 2A-2B.

At operation 300, first operation data is obtained for a rear door heat exchanger positioned with the rack. The first operation data may be obtained by (i) requesting, from a controller of the rear door heat exchanger, data specifying operations facilitated by the rear door heat exchanger as well as data specifying conditions in which such operations may be facilitated, and (ii) obtaining this requested data.

As discussed with regard to FIGS. 2A-2B, for example, this first operation data may specify a state that is at least partially manageable by the thermal regulation framework, the first operation data specifying the state in which the rear door heat exchanger operates. The requested data may therefore be obtained, for example, via data transmissions between a system orchestrator of the rack (e.g., 102) and the controller of the rear door heat exchanger (e.g., 104) as discussed with respect to FIG. 2A (e.g., data transmission 222).

At operation 302, second operation data is obtained for the data processing systems. The second operation data may be obtained by (i) requesting, from management controllers (e.g., 110-111) of the data processing systems, data specifying operations facilitated by the data processing systems, respectively, as well as data specifying conditions in which such operations may be facilitated, and (ii) obtaining this requested data.

For example, also as discussed with regard to FIGS. 2A-2B, this second operation data may specify states that are at least partially manageable by the thermal regulation framework (e.g., may include first data processing system operating conditions 244 and/or second data processing system operating conditions 246 discussed in FIGS. 2A-2B), the second operation data specifying the states in which the data processing systems operate. Therefore, similar to obtaining the prior requested data, this requested data may be obtained, for example, via data transmissions between the system orchestrator of the rack (e.g., 102) and the management controllers of the first data processing system and the second data processing system (e.g., 110-111) as discussed with respect to FIG. 2A (e.g., data transmissions 224-226 shown in FIG. 2A).

At operation 304, first operating points for a cooling system of the rear door heat exchanger and second operating points for cooling systems of the data processing systems are obtained using the first operation data and the second operation data. For example, the first operating points and the second operating points may be obtained by ingesting the first operation data and the second operation data into a cooling instruction generation process in which the first and the second operation data may be subject to any number of filtering and/or analysis processes. Such filtering and/or analysis processes may be implemented using an optimization algorithm.

For example, due to the first operation data and the second operation data specifying respective states of devices that may be at least partially manageable by the thermal regulation framework, the operating points may be based on such operation data as the first operation data and the second operation data. Therefore, the optimization algorithm may include, (i) identifying what cooling requirements may be necessary for the data processing systems (and/or the RDHx) based on the first operation data and the second operation data, (ii) identifying what power consumption requirements may be known for the identified cooling requirements, (iii) making a determination regarding what combinations of cooling processes meet the cooling requirements while also mitigating power consumption of the data processing systems (and/or the RDHx).

To do so, the optimization algorithm may be incentivized to (i) globally minimize power consumption by the cooling system of the rear door heat exchanger and the cooling systems of the data processing systems, (ii) maintain temperatures of the data processing systems within predefined temperature ranges, and (iii) ensure completion of workloads performed by the data processing systems within predefined time ranges. To incentivize such things, the optimization algorithm may utilize an objective function that quantifies potential operating points for the cooling system of the RDHx and potential operating points for the cooling systems of the data processing systems based, at least, on power consumption, the temperatures of the data processing systems, and the predefined time ranges to complete the workloads. This objective function may provide a functionality such as that discussed with regard to cooling instruction generation 228 in FIG. 2B.

For example, the first operation data may specify that (i) the RDHx is operating at 10% its maximum capacity with a first fan of the RDHx causing half of that 10% operating capacity (e.g., the first fan being positioned with a server chassis of the first data processing system and discussed with regard to server chassis 212A in FIG. 1B), and that (ii) the second operation data may specify respective schedules of workloads for the data processing systems to perform as well as each data processing system's power consumption associated with cooling (and/or other) processes being performed. Additionally, assume a scenario in which the system orchestrator (e.g., as discussed in FIGS. 1A-2G) identifies a change in the cooling requirements of the rack. Furthermore, assume the system orchestrator identifies a request made to the first data processing system to perform a workload that will make components of the first data processing system generate additional heat within the rack. The system orchestrator may then request operation data (the first and the second operation data) from various devices in the system such as from the RDHx and the first and the second data processing systems. This operation data may then be ingested into an optimization algorithm as discussed with regard to FIG. 2B.

As discussed with respect to FIG. 2B, the cooling instructions obtained may include new operating points (the first and the second operating points), these new operating points being, for example, conditions to be set by (e.g., new parameters for specific operation of a component that may be established by) commands provided to components (e.g., the component) of the RDHx, the first data processing system, and/or the second data processing system to change respective component operations for cooling while mitigating power consumption of the data processing systems.

In the example given above with regard to the RDHx operating at 10% its maximum capacity, such commands to set new parameters to sufficiently cool the first and the second data processing systems after the obtaining the workload performance request may include instructions for the RDHx to increase that 10% operation to a 50% operation. For example, such commands may further include the first fan of the RDHx to operate such that it causes half of that 50% operating capacity of the RDHx. In this case, the new operating points may include, for example, the new rpm of the first fan to facilitate the change from 10% to 50% operating capacity of the RDHx.

At operation 306, operation of the cooling system and the cooling systems are set using the first operating points and the second operating points to obtain an updated rack. The operation of the cooling system and the cooling systems may be set, for example, by providing the above-mentioned commands to relevant and respective components of the RDHx, the first data processing system, and/or the second data processing system. In doing so, the new parameters may be established. For example, in the example given above, providing a command to the RDHx controller to increase the rpm of the first fan based on the new operating points may cause the discussed change in operation of the RDHx. Thus, the RDHx may sufficiently cool the data processing systems during performance of the requested workload.

In doing so, the previously discussed operating points may be used to change respective component operations for cooling. This means that the operation of the cooling system and the operation of the cooling systems may be changed based on the operating points. Therefore, the operating points may be commands provided to components of the RDHx, the first data processing system, and/or the second data processing system to change respective component operations for cooling (e.g., change operation of the cooling system and the cooling systems). Thus, when these commands are followed by the respective components, the operation of the cooling system and the operation of the cooling systems may be set.

Once set, the new operations of said cooling systems may, thus, cause the obtaining of the updated rack (e.g., the rack, but with updated operations).

At operation 308, computer implemented services are provided using the updated rack. The computer implemented services may be provided by performing the above-mentioned updated operations, the updated operations being performed by the updated rack to provide the computer implemented services as expected/desired by a consumer of the computer implemented services.

For example, providing the computer implemented services may include (i) obtaining, by the data processing systems, workload performance requests, and (ii) performing, by the data processing systems while the first operating points for the cooling system and the second operating points for the cooling systems are enforced (e.g., due to the rack having updated operations), workloads based on the workload performance requests.

The first method may end following operation 308.

Turning to FIG. 3B, a second flow diagram illustrating a method (e.g., a second method) for managing operation of data processing systems positioned in a rack in accordance with an embodiment is shown. The method may be performed, for example, by a RDHx controller, and/or any other entity.

For example, the second method may be that which is discussed with respect to a second portion of a thermal regulation framework as discussed with respect to FIGS. 2C-2D.

At operation 310, operation data for the data processing systems is obtained from management controllers of the data processing systems. The operation data may be obtained by (i) requesting, from management controllers (e.g., 110-111) of the data processing systems, data specifying operations facilitated by the data processing systems, respectively, as well as data specifying conditions in which such operations may be facilitated, and (ii) obtaining this requested data.

It will be appreciated that the operation data mentioned above (with respect to FIG. 3B) may include information such as that discussed with regard to the second operation data in FIG. 3A and may be mentioned in such a manner within this discussion to compartmentalize various portions (e.g., the first portion discussed with regard to the first method in FIG. 3A, the second portion discussed with regard to the second method in FIG. 3B, and the third portion being discussed with regard to the third method in FIG. 3C) of the thermal regulation network.

It will further be appreciated that the management controller of the RDHx may also be able to obtain operating conditions of the RDHx as discussed with regard to FIGS. 2A-2B). However, such operating conditions may not be explicitly discussed due to (i) an attempt at highlighting the importance of the data processing systems'operating conditions in this discussion, and (ii) already being accessible to the management controller of the RDHx due to the management controller of the rear door heat exchanger being an embedded controller of the RDHx (and therefore, operation of the management controller of the rear door heat exchanger being independent from the data processing systems, the management controllers of the data processing systems, and an orchestrator tasked with managing operation of the data processing systems).

For example, similar to the second operation data discussed with regard to FIG. 3A, this operation data may specify a state that is at least partially manageable by the thermal regulation framework, the operation data specifying the states in which the data processing systems (e.g., the first and the second data processing systems) operate. The requested data may therefore be obtained, for example, via data transmissions between the RDHx controller (e.g., 104) positioned with the rack and the controllers of the data processing systems (e.g., 110-111) as discussed with respect to FIG. 2C (e.g., data transmissions 258-259).

At operation 312, operating points for a cooling system of the rear door heat exchanger are obtained using the operation data. The operating points may be obtained by ingesting the operation data into a cooling optimization process in which the operation data may be subject to any number of filtering and/or analysis processes. Such filtering and/or analysis processes may be implemented using an optimization algorithm (e.g., this algorithm may be a same or a different algorithm to that discussed with regard to FIG. 3A). Additionally, it will be appreciated that, due to each of the data processing systems including a corresponding cooling system that operates independently of the cooling system of the rear door heat exchanger, the operating points for the cooling system of the rear door heat exchanger may be different from other possible operating points that may be obtained for the cooling systems of the data processing systems.

For example, due to the operation data specifying respective states of devices that may be at least partially manageable by the thermal regulation framework, the operating points may be based on this operation data. Therefore, this optimization algorithm may include, (i) identifying what cooling requirements may be necessary for the data processing systems (and/or the RDHx) based on the operation data obtained, (ii) identifying what power consumption requirements may be known for the identified cooling requirements, (iii) making a determination regarding what combinations of cooling processes meet the cooling requirements while also mitigating power consumption of the data processing systems (and/or the RDHx). Such a combination of cooling processes may include, for example, processes performable by the RDHx.

To provide this algorithmic functionality, this optimization algorithm may be incentivized to (i) globally minimize power consumption by the cooling system of the rear door heat exchanger and the cooling systems of the data processing systems, (ii) maintain temperatures of the data processing systems within predefined temperature ranges, and (iii) ensure completion of workloads performed by the data processing systems within predefined time ranges.

To incentivize such things, the optimization algorithm may utilize an objective function that quantifies potential operating points for the cooling system of the RDHx and potential operating points for the cooling systems of the data processing systems based, at least, on power consumption, the temperatures of the data processing systems, and the predefined time ranges to complete the workloads. This objective function may provide a functionality such as that discussed with regard to cooling optimization 262 in FIG. 2D.

For example, assume that the data processing systems require respective central processing units (CPUs) to have operating temperatures below 65 degrees Celsius. Now further assume that the first data processing system's CPU is about to be operating at a temperature of 80 degrees Celsius based on a workload request received by the first data processing system. Simultaneously, the second data processing system's CPU is about to be operating at a temperature of 50 degrees Celsius based on another workload request received by the second data processing system. These (e.g., soon-to-be) CPU temperatures may be included in the operation data that may have been requested by the RDHx controller (104) based on identification of the aforementioned workload requests to the first and the second data processing systems, respectively. Therefore, for example, despite the second data processing system's CPU predicted to operate within required operating temperatures, the RDHx controller may provide a baseline-type of cooling for the data processing systems in order to cool the first data processing system while also providing cooling for other data processing systems positioned with the rack such as the second data processing system.

For example, based on the operation data, operating points for the RDHx may be obtained that, when used to set operation, cool both data processing systems such that (i) the first data processing system's CPU may operate within the required temperature threshold instead of operating at 80 degrees Celsius, and (ii) the second data processing system is provided with additional cooling.

For example, as discussed with respect to FIG. 2D, the optimized cooling instructions obtained may include the new operating points. These operating points may be, first conditions to be set by (e.g., new parameters for specific operation of a component that may be established by) first commands provided to components (e.g., the component) of the rear door heat exchanger system to change respective component operations for cooling while mitigating power consumption of the data processing systems.

It will be appreciated that in some cases where, after components of the RDHx have instantiated said first commands, the other possible operating points (e.g., second conditions to be set by second commands provided to components of the data processing systems.

It will also be appreciated that these commands (e.g., the first and/or the second commands), when followed, mitigate power consumption of the data processing systems while preventing workload loss (e.g., by providing sufficient cooling for workloads to be completed). For example, this power consumption may be mitigated due to the RDHx providing a majority of the cooling for the rack, allowing the data processing systems to not be required to consume a high percentage of resources available in order to provide cooling for themselves.

At operation 314, operation of the cooling system is set using the operating points to obtain an updated rack. The operation may be set by, for example, providing the above-mentioned commands to the components of the RDHx (e.g., optimized cooling instructions 260), thereby causing the components to cool multiple of the data processing systems at a same rate and/or cool any number of the data processing systems at different rates. In doing so, operation of the RDHx may be updated. Additionally, in some cases where the data processing systems require additional cooling beyond what is provided by the updated operation, the first data processing system (e.g., via supplemental cooling process 268A) and/or the second data processing system (e.g., via supplemental cooling process 268B) may have their own operations set and therefore updated. For example, these updated operations of the data processing systems may be based on the other possible operating points, previously mentioned.

It will be appreciated that in such aforementioned cases, and as discussed with regard to FIGS. 2C-2D, the RDHx controller may, for example, automatically cause the data processing systems to update their respective processes based on this supplemented (baseline-type) cooling provided by the RDHx. For example, the data processing systems may identify condition changes independently from other devices positioned with the rack, and thus, may update their own operations independently as well.

Alternatively, for example, the RDHx controller may provide updated condition data indicating conditions of itself, the rack, individual servers, and/or the ambient environment to any devices positioned with the rack. These devices may, in turn, react to such provided updated condition data depending on various operating algorithms and default functionalities of these devices.

It will be appreciated that in some cases the management controllers of the data processing systems may be notified, prior to the updating of the rear door heat exchanger's operation, of (i) the operating points and/or (ii) a plan for the updating of the rear door heat exchanger's operation based on the operating points. Based on such notification, the data processing systems may be enabled to proactively modify their cooling behavior to compensate for the updating of the operation of the rear door heat exchanger.

Thus, such changes to operations of the RDHx and/or any other devices positioned with the rack (e.g., updated operations of the rack) may result in an updated rack.

At operation 316, computer implemented services are provided using the updated rack. The computer implemented services may be provided by performing the above-mentioned updated operations, the updated operations being performed by the updated rack to provide the computer implemented services as expected/desired by a consumer of the computer implemented services.

For example, providing the computer implemented services may include (i) obtaining, by the data processing systems, workload performance requests, and (ii) performing, by the data processing systems while the operating points for the cooling system (and in some cases, while the other possible operating points for the cooling systems) are enforced (e.g., due to the rack having updated operations), workloads based on the workload performance requests.

The second method may end following operation 316.

Turning to FIG. 3C a third flow diagram illustrating a method (e.g., a third method) for managing operation of data processing systems positioned in a rack in accordance with an embodiment is shown. The method may be performed, for example, by a management controller of a data processing system of the data processing systems, and/or any other entity.

For example, the third method may be that which is discussed with respect to a third portion of a thermal regulation framework as discussed with respect to FIGS. 2E-2G.

At operation 320, a determination is made regarding whether an occurrence of a thermal management event is identified. The determination may be made by comparing immediate processes that are ongoing and processes of which performance is imminent to identify whether known cooling requirements of said processes vary, and if they vary to what degree of variance. If the variance (should there be a variance) is above a pre-determined variance threshold, for example, there may be an increased likelihood of there being new cooling requirements that have not yet been met. Such a state in which cooling requirements have not been met may thus be regarded (e.g., identified) as an occurrence of a thermal management event (e.g., such an occurrence may be like that of the trigger event discussed in FIGS. 2E-2G). Thus, for example, the thermal management event may be an event that initiates updating of data processing system operation, as discussed further below.

If determined that the occurrence of the thermal management event is identified, then the third method may proceed to operation 322. Otherwise, the third method may end following operation 320.

At operation 322, first operation data is obtained for the data processing system (e.g., the first data processing system discussed previously). The first operation data may be obtained by (i) requesting, from components of the data processing system, data specifying operations facilitated by the data processing system as well as data specifying conditions in which such operations may be facilitated, and (ii) obtaining this data based on the request.

It will be appreciated that the operation data may include information such as that discussed with regard to the operation data in FIGS. 2F-2G and may be mentioned in such a manner within this discussion to compartmentalize various portions (e.g., the first portion discussed with regard to the first method in FIG. 3A, the second portion discussed with regard to the second method in FIG. 3B, and the third portion being discussed with regard to the third method in FIG. 3C) of the thermal regulation network.

At operation 324, operating points are obtained for a cooling system of a rear door heat exchanger (e.g., the RDHx discussed previously) and a cooling system of the data processing system. These operating points may be obtained by ingesting the operation data into a supplemental cooling instruction generation process in which the operation data may be subject to any number of filtering and/or analysis processes. Such filtering and/or analysis processes may be implemented using an optimization algorithm.

It will be appreciated that this algorithm may be a same or a different algorithm to that discussed with regard to FIGS. 3A-3B. For example, some primary differences in utilization of such an algorithm throughout this discussion may include different portions of the thermal regulation network being primarily facilitated at different levels of system control (e.g., local-level authority over independent server operation, senior-level authority over most if not all other device operation in the rack, supplemental-level authority over an independent fringe device with some authority over some of the other components, etc.) over the rack to optimize operation of the rack using the algorithm.

It will be further appreciated that, due to the data processing system including a corresponding cooling system that operates independently of the cooling system of the rear door heat exchanger, the operating points for the cooling system of the rear door heat exchanger may be based on operating condition data regarding the data processing system as well as the RDHx (e.g., rear door heat exchanger operating conditions 242 discussed in FIG. 2B).

For example, due to the operation data specifying operating conditions of the data processing system that may be at least partially manageable by the thermal regulation framework, the operating points may be based on this operation data. Therefore, this optimization algorithm may include, (i) identifying what cooling requirements may be necessary for the data processing system (e.g., in some cases, also the RDHx depending on whether the data processing system is capable of obtaining communications from the RDHx) based on the operation data obtained, (ii) identifying what power consumption requirements may be known for the identified cooling requirements, (iii) making a determination regarding what combinations of cooling processes meet the cooling requirements while also mitigating power consumption of the data processing systems. Such a combination of cooling processes may include, for example, processes performable by the data processing system (e.g., and in some cases, the RDHx as previously mentioned).

To provide this algorithmic functionality, this optimization algorithm may be incentivized to (i) globally minimize power consumption by the cooling system of the data processing system (and/or the cooling system of the rear door heat exchanger), (ii) maintain temperatures of the data processing system (and therefore, the rack) within predefined temperature ranges, and (iii) ensure completion of workloads performed by the data processing systems within predefined time ranges.

To incentivize such things, the optimization algorithm may utilize an objective function that quantifies potential operating points for the cooling system of the data processing system based, at least, on power consumption, the temperatures of the rack and accompanying devices, and the predefined time ranges to complete the workloads. This objective function may provide a functionality such as that discussed with regard to supplemental cooling instruction generation 272 in FIG. 2F and/or automatic condition management process 280 in FIG. 2G.

For example, based on the operation data, operating points for the data processing system may be obtained that, when used to set operations of cooling systems, cause the data processing system to operate within the required operating conditions instead of operating in conditions that risk workload loss and/or risk delays associated with performance of the workloads.

For example, as discussed with respect to FIG. 2F (and/or FIG. 2G), the supplemental cooling instructions (and/or the updated cooling operations) obtained may include the new operating points. These operating points may be parameters within which operating conditions may be established by providing commands to components of the data processing system to set operation of the cooling system of the data processing system.

It will be appreciated that in some cases where, after components of the data processing system have carried out such commands, other parameters may be set based on the operating points (e.g., specific supplemental cooling process 278 discussed in FIG. 2E).

It will be further appreciated that such commands, when followed, may mitigate power consumption of the data processing system, the data processing systems, and/or other devices positioned with the rack while preventing workload loss (e.g., by providing sufficient cooling and maintain available power reserves for workloads to be completed).

At operation 326, operation of the cooling system of the rear door heat exchanger and operation of the cooling system of the data processing system are set using the operating points to obtain an updated rack. These operations may be set, for example, by providing commands to perform processes that establish new operating conditions to relevant and respective components of the data processing system (and/or the RDHx), the new operating conditions being within parameters indicated by the operating points. By establishing the new operating conditions for the data processing system, operation of the rack may be updated to obtain the updated rack.

In some cases, the RDHx may also be updated as discussed in FIGS. 2E-2G. For example, should the management controller of the data processing system have capability to communicate with the RDHx (e.g., the management controller of the RDHx), then a management controller of the rear door heat exchanger may be notified of, for example, the operating points prior to updating operation of hardware components of the data processing system to enable the rear door heat exchanger to proactively modify cooling behavior to compensate for the updating of the operation of the hardware components,

At operation 328, computer implemented services are provided using the updated rack. The computer implemented services may be provided by performing the above-mentioned updated operations, the updated operations being performed by the updated rack to provide the computer implemented services as expected/desired by a consumer of the computer implemented services.

The third method may end following operation 328.

Thus, using the methods illustrated in FIGS. 3A-3C, embodiments disclosed herein may manage data processing systems to increase a likelihood of providing desired computer implemented services while mitigating power consumption and preventing workload loss for the data processing systems.

Any of the processes and/or components illustrated in and/or discussed with regard to FIGS. 1A-3C may be implemented with and/or used in conjunction with one or more computing devices.

Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as a keyboard or thermal sensor may be controlled by an embedded controller (not shown), dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method for managing operation of data processing systems positioned in a rack, the method comprising:
identifying, by a management controller of a data processing system of the data processing systems, an occurrence of a thermal management event;
based on the occurrence:
obtaining, by the management controller, first operation data for the data processing system;
obtaining, by the management controller, operating points for a cooling system of a rear door heat exchanger and a cooling system of the data processing system;
setting, by the management controller and using the operating points, operation of the cooling system of the rear door heat exchanger and operation of the cooling system of the data processing system to obtain an updated rack; and
providing computer implemented services using the updated rack.

2. The method of claim 1, wherein each of the cooling system of the data processing system operates independently from the cooling system of the rear door heat exchanger.

3. The method of claim 2, wherein obtaining the operating points comprises:
calculating the operating points using an optimization algorithm.

4. The method of claim 3, wherein the optimization algorithm is incentivized to globally minimize power consumption by the cooling system of the data processing system.

5. The method of claim 4, wherein the optimization algorithm is further incentivized to maintain temperatures of the data processing system within predefined temperature ranges.

6. The method of claim 5, wherein the optimization algorithm is further incentivized to ensure completion of workloads performed by the data processing system within predefined time ranges.

7. The method of claim 6, wherein the optimization algorithm utilizes an objective function that quantifies potential operating points for the cooling system of the data processing systems based, at least, on power consumption, the temperatures of the data processing system, and the predefined time ranges to complete the workloads.

8. The method of claim 7, wherein the first operation data comprises:
power consumption demands placed on the data processing system for completion of at least a portion of the workloads;
internal server chassis temperatures of the data processing system;
ambient temperature data of the rack;
individual component temperatures of hardware components of the data processing system; and
fan rotation speeds of fans of the cooling system of the data processing system.

9. The method of claim 8, wherein the operating points for the cooling system of the rear door heat exchanger is also based on second operation data for the rear door heat exchanger, the second operation data comprising:
power consumption demands placed on the rear door heat exchanger;
inlet and outlet air temperatures of the rear door heat exchanger;
position data specifying locations of fans and other cooling components of the rear door heat exchanger relative to positions of the data processing systems in the rack;
fan rotation speeds of the fans of the rear door heat exchanger;
liquid flow control data for a liquid cooling path within the rack; and
inlet and outlet fluid temperatures for the liquid cooling path.

10. The method of claim 1, wherein a management controller of the rear door heat exchanger is an embedded controller that operates independently from the management controller of the data processing system, and an orchestrator tasked with managing operation of the data processing systems positioned in the rack.

11. The method of claim 1, further comprising:
notifying, by the management controller of the data processing system, a management controller of the rear door heat exchanger of the operating points prior to updating operation of hardware components of the data processing system to enable the rear door heat exchanger to proactively modify cooling behavior to compensate for the updating of the operation of the hardware components,
wherein the thermal management event is an event that initiated updating of the operation of the hardware components.

12. The method of claim 1, wherein the rear door heat exchanger is adapted to cool multiple of the data processing systems at a same rate.

13. The method of claim 10, wherein the rack comprises:
the data processing systems;
the management controllers of the data processing systems;
the rear door heat exchanger;
the management controller of the rear door heat exchanger; and
the orchestrator.

14. A non-transitory machine-readable medium having instructions stored therein, which when executed by a processor, cause the processor to perform operations for managing operation of data processing systems positioned in a rack, the operations comprising:
identifying, by a management controller of a data processing system of the data processing systems, an occurrence of a thermal management event;
based on the occurrence:
obtaining, by the management controller, first operation data for the data processing system;
obtaining, by the management controller, operating points for a cooling system of a rear door heat exchanger and a cooling system of the data processing system;
setting, by the management controller and using the operating points, operation of the cooling system of the rear door heat exchanger and operation of the cooling system of the data processing system to obtain an updated rack; and
providing computer implemented services using the updated rack.

15. The non-transitory machine-readable medium of claim 14, wherein the cooling system of the data processing system operates independently from the cooling system of the rear door heat exchanger.

16. The non-transitory machine-readable medium of claim 15, wherein obtaining the operating points comprises:
calculating the operating points using an optimization algorithm.

17. The non-transitory machine-readable medium of claim 14, wherein a management controller of the rear door heat exchanger is an embedded controller that operates independently from the management controller of the data processing system, and an orchestrator tasked with managing operation of the data processing systems positioned in the rack.

18. A management controller of a data processing system of a rack adapted to perform a method for managing operation of data processing systems positioned in the rack, the method comprising:
identifying, by the management controller of the data processing system of the data processing systems, an occurrence of a thermal management event;
based on the occurrence:
obtaining, by the management controller, first operation data for the data processing system;
obtaining, by the management controller, operating points for a cooling system of a rear door heat exchanger and a cooling system of the data processing system;
setting, by the management controller and using the operating points, operation of the cooling system of the rear door heat exchanger and operation of the cooling system of the data processing system to obtain an updated rack; and
providing computer implemented services using the updated rack.

19. The management controller of claim 18, wherein obtaining the operating points comprises:
calculating the operating points using an optimization algorithm.

20. The management controller of claim 18, wherein a management controller of the rear door heat exchanger is an embedded controller that operates independently from the management controller of the data processing system and an orchestrator tasked with managing operation of the data processing systems positioned in the rack.
